(19) United States
(12) Patent Application Publication
(10) Pub. No.: US 2025/0169066 A1
(43) Pub. Date: May 22, 2025

(54) SEMICONDUCTOR DEVICE INCLUDING WORD LINE SIGNAL PATH

(71) Applicant: Samsung Electronics Co., Ltd., Suwon-si (KR)

(72) Inventors: Daesun Kim, Suwon-si (KR); Suklae Kim, Suwon-si (KR); Cheonbae Kim, Suwon-si (KR); Youngseok Park, Suwon-si (KR); Taejin Park, Suwon-si (KR); Hyunchul Yoon, Suwon-si (KR); Hyeonkyu Lee, Suwon-si (KR); Sungsoo Yim, Suwon-si (KR); Hyungeun Choi, Suwon-si (KR)

(21) Appl. No.: 18/826,334

(22) Filed: Sep. 6, 2024

(30) Foreign Application Priority Data
Nov. 16, 2023 (KR) 10-2023-0159443
Mar. 11, 2024 (KR) 10-2024-0033686

(51) Int. Cl. H10B 12/00; G11C 11/408; G11C 11/4091; H01L 23/00; H01L 25/065; H01L 25/18

(52) U.S. Cl. CPC H10B 12/50; G11C 11/4085; G11C 11/4091; H01L 24/08; H01L 25/0657; H01L 25/18; H10B 12/315; H01L 2224/08145; H01L 2924/1431; H01L 2924/1436

(57) ABSTRACT

Provided is a semiconductor device. The semiconductor device includes: a first connection region, a first memory block region, and a second connection region sequentially arranged; a first peripheral circuit region vertically overlapping with the first memory block region; first memory cells in the first memory block region; a first word line extending into the first and second connection regions by crossing the first memory block region, and electrically connected to the first memory cells; a first sub-word line driver in the first peripheral circuit region; and a first word line signal path electrically connecting the first word line and the first sub-word line driver. The first word line signal path includes at least one first routing contact coupled to the first word line in the first connection region, and at least one second routing contact coupled to the first word line in the second connection region.

### CROSS-REFERENCE TO RELATED APPLICATION(S)

This application claims benefit of priority to Korean Patent Application No. 10-2023-0159443 filed on Nov. 16, 2023, and Korean Patent Application No. 10-2024-0033686 filed on Mar. 11, 2024, in the Korean Intellectual Property Office, the disclosures of which are incorporated herein by reference in their entirety.

### BACKGROUND OF THE INVENTION

The present disclosure relates to a semiconductor device including a word line signal path.

Research is being conducted to reduce the size and improve the performance of the elements constituting semiconductor devices. For example, in a dynamic random-access memory (DRAM), research is being conducted to reliably and stably form elements of reduced size, but with a decrease in the size of the elements, the performance of semiconductor devices can deteriorate.

### SUMMARY OF THE INVENTION

An aspect of the present disclosure is to provide a semiconductor device that may increase a degree of integration and improve performance.

According to an aspect of the present disclosure, provided is a semiconductor device. The semiconductor device includes: a first structure having a first connection region, a second connection region, and a first memory block region that is between, in a first direction, the first connection region and the second connection region; and a second structure vertically overlapping with the first structure. The first structure includes: first memory cells in the first memory block region; and a first word line crossing the first memory block region and extending into the first and second connection regions, and electrically connected to the first memory cells, the second structure has a first peripheral circuit region, at least a portion of which is vertically overlapping with the first memory block region, the second structure includes a first sub-word line driver in the first peripheral circuit region, the first and second structures further include a first word line signal path electrically connecting the first word line and the first sub-word line driver, and the first word line signal path includes at least one first routing contact coupled to the first word line in the first connection region, and at least one second routing contact coupled to the first word line in the second connection region.

According to an aspect of the present disclosure, provided is a semiconductor device. The semiconductor device includes: a first connection region, a second connection region, and a first memory block region that is between, in a first direction, the first connection region and the second connection region; a first peripheral circuit region vertically overlapping with the first memory block region; first memory cells in the first memory block region; a first word line extending into the first and second connection regions by crossing the first memory block region, and electrically connected to the first memory cells; a sub-word line driver in the first peripheral circuit region; and a first word line signal path electrically connecting the first word line and the sub-word line driver. The first word line signal path includes at least one first routing contact coupled to the first word line in the first connection region, and at least one second routing contact coupled to the first word line in the second connection region.

According to an aspect of the present disclosure, provided is a semiconductor device. The semiconductor device includes: a first structure including connection regions and memory block regions alternately and repeatedly arranged in a first direction; and a second structure arranged in the first direction, including peripheral circuit regions, and vertically overlapping with the first structure. The connection regions include a first edge connection region, a second edge connection region, and intermediate connection regions between the first edge connection region and the second edge connection region, and each of the memory block regions is between a pair of adjacent connection regions among the connection regions. The first structure includes: memory cells in each of the memory block regions; and word lines electrically connected to the memory cells by crossing the memory block regions and extending into the connection regions. The second structure includes sub-word line drivers in each of the peripheral circuit regions. The first and second structures further include word line signal paths electrically connecting the word lines and the sub-word line drivers. The word line signal paths include: routing interconnection lines crossing the memory block regions and extending into the connection regions; routing contacts in each of the connection regions and electrically connecting the word lines and the routing interconnection lines; and routing structures electrically connecting the routing interconnection lines and the sub-word line drivers.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1A, 1B, 2A-2C, 3, 4, 5A-5C, 6, 7A-7D, 8, 9A, and 9B are views illustrating an example of a semiconductor device according to an example embodiment of the present disclosure;

FIGS. 10, 11A, and 11B are views illustrating an example of a semiconductor device according to an example embodiment of the present disclosure;

FIGS. 12A, 12B, and 12C are views illustrating an example of a semiconductor device according to an example embodiment of the present disclosure;

FIG. 13 is a perspective view illustrating an example of a semiconductor device according to an example embodiment of the present disclosure;

FIGS. 14 and 15 are views illustrating an example of a semiconductor device according to an example embodiment of the present disclosure;

FIGS. 16 and 17 are views illustrating an example of a semiconductor device according to an example embodiment of the present disclosure;

FIGS. 18A and 18B are views illustrating an example of a semiconductor device according to an example embodiment of the present disclosure;

FIG. 19A is a view illustrating an example of a semiconductor device according to an example embodiment of the present disclosure;

FIG. 19B is a view illustrating an example of a semiconductor device according to an example embodiment of the present disclosure;

FIG. 19C is a view illustrating an example of a semiconductor device according to an example embodiment of the present disclosure;

FIG. 20 is a view illustrating an example of a semiconductor device according to an example embodiment of the present disclosure;

FIG. 21 is a view illustrating an example of a semiconductor device according to an example embodiment of the present disclosure;

FIG. 22 is a cross-sectional view illustrating an example of a semiconductor device according to an example embodiment of the present disclosure;

FIG. 23 is a cross-sectional view illustrating an example of a semiconductor device according to an example embodiment of the present disclosure;

FIG. 24 is a cross-sectional view illustrating an example of a semiconductor device according to an example embodiment of the present disclosure; and

FIG. 25 is a cross-sectional view illustrating an example of a semiconductor device according to an example embodiment of the present disclosure.

### DETAILED DESCRIPTION

Hereinafter, the terms such as “upper,” “intermediate,” and “lower” may be replaced with other terms such as “first,” “second,” and “third” and may be used to describe elements of the specification. The terms such as “first,” “second,” and “third” may be used to describe various elements, but the elements are not limited thereto, and the “first element” could be termed “second element.”

In the specification, terms such as ‘lower,’ ‘upper,’ ‘top,’ and ‘bottom’ may be terms explained based on the drawings.

In the drawings, marks in the form of ‘M(M1)’ and ‘M(M2)’ have a plurality of elements referred to as ‘M,’ and the plurality of elements referred to as ‘M’ may be defined as including a first element referred to as ‘M1’ and a second element referred to as ‘M2.”

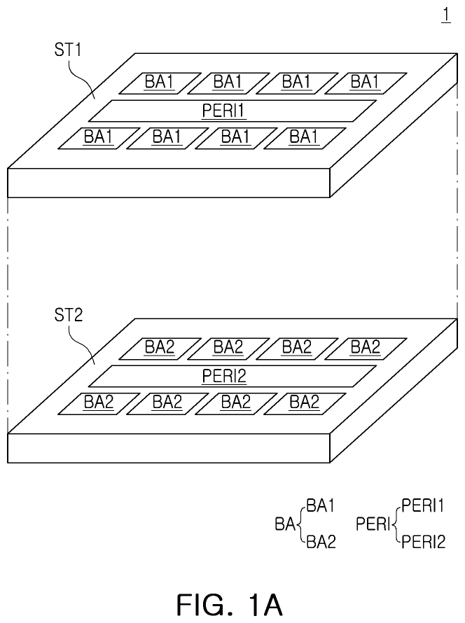

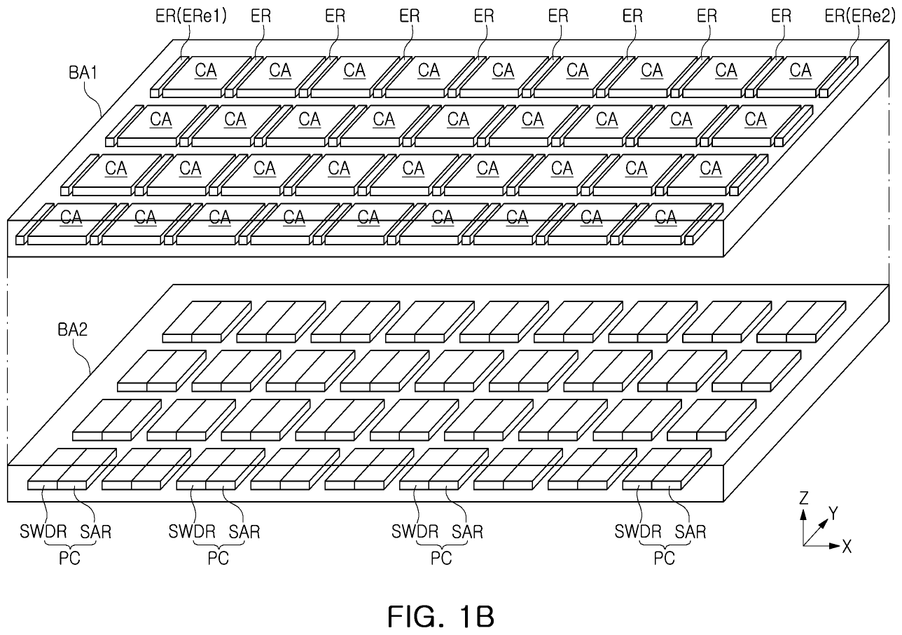

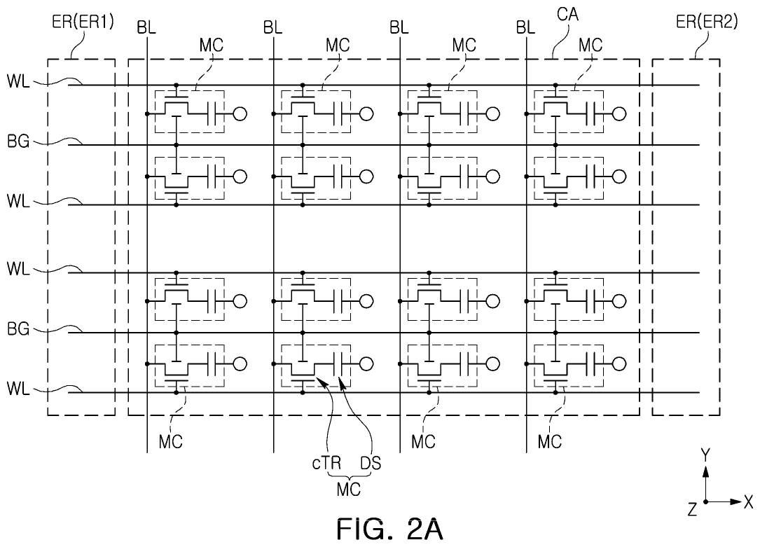

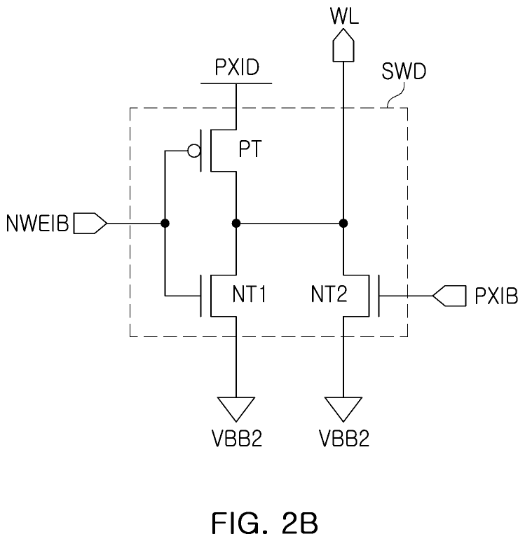

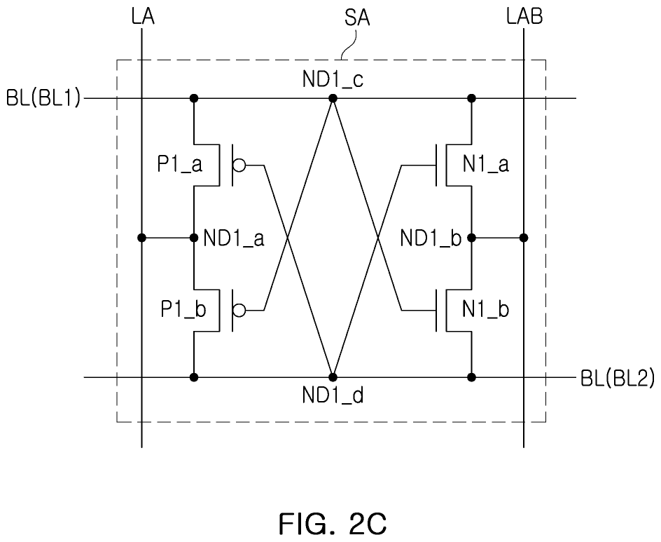

First, an example of a semiconductor device according to an example embodiment of the present disclosure will be described with reference to FIGS. 1A, 1B, 2A, 2B, and 2C. In FIGS. 1A, 1B, 2A, 2B, and 2C, FIG. 1A is a perspective view conceptually illustrating an example of a semiconductor device according to an example embodiment of the present disclosure, FIG. 1B is a perspective view conceptually illustrating a portion of FIG. 1A, FIG. 2A is a circuit diagram illustrating an example of a memory block in a memory block region of a semiconductor device according to an example embodiment of the present disclosure, FIG. 2B is a circuit diagram illustrating an example of a sub-word line driver in a peripheral circuit region of a semiconductor device according to an example embodiment of the present disclosure, and FIG. 2C is a circuit diagram illustrating an example of a sense amplifier in a peripheral circuit region of a semiconductor device according to an example embodiment of the present disclosure.

First, referring to FIGS. 1A and 1B, a semiconductor device 1 according to an example embodiment may include a first structure ST1 and a second structure ST2 vertically overlapping with (e.g., vertically overlapped by) the first structure ST1. As used herein, the phrase “B is vertically overlapped by A” means that A is on top of B (and that a vertical axis extends through both A and B). The first structure ST1 may be disposed on (e.g., on top of) the second structure ST2.

In an example embodiment, the first structure ST1 may be a first chip structure including memory cells, and the second structure ST2 may be a second chip structure including a peripheral circuit capable of operating memory cells. The first structure ST1 and the second structure ST2 may be formed by being bonded through a bonding process such as a wafer bonding process. Accordingly, the first structure ST1 may be in contact with and bonded to the second structure ST2.

The semiconductor device 1 may include a plurality of banks BA and a peripheral region PERI.

The peripheral region PERI may include a first peripheral region PERI1 in the first structure ST1 and a second peripheral region PERI2 in the second structure ST2. The peripheral region PERI may be a peripheral circuit region in which peripheral circuits for input/output of data or commands, or power/ground input are disposed.

Each of the plurality of banks BA may include a first bank region BA1 in the first structure ST1 and a second bank region BA2 in the second structure ST2.

The first bank region BA1 in the first structure ST1 may include memory block regions CA and connection regions ER.

The memory block regions CA may be arranged in a first direction (X-direction) and a second direction (Y-direction). The first direction (X-direction) and the second direction (Y-direction) may be perpendicular to each other. The connection regions ER may be disposed on opposite (e.g., both) sides of each of the memory block regions CA. For example, the memory block regions CA and the connection regions ER may be alternately and repetitively arranged in the first direction (X-direction). Among the memory block regions CA and the connection regions ER alternately and repeatedly arranged in the first direction (X-direction), each of the memory block regions CA may be disposed between a pair of adjacent connection regions ER in the first direction (X-direction). The connection regions ER may also be referred to as extension regions. The connection regions ER may include a first edge connection region ERe1, a second edge connection region ERe2, and intermediate connection regions ER disposed between the first edge connection region ERe1 and the second edge connection region ERe2. Each of the memory block regions CA may be disposed between a pair of adjacent connection regions ER, among the connection regions ER.

The second bank region BA2 in the second structure ST2 may include peripheral circuit regions PC. The peripheral circuit regions PC may be arranged in the first direction (X-direction) and the second direction (Y-direction). The peripheral circuit regions PC may overlap the memory block regions CA in a vertical direction (Z-direction). Each of the peripheral circuit regions PC may include a sense amplifier region SAR and a sub-word line driver region SWDR.

Next, referring to FIG. 2A along with FIGS. 1A and 1B, the connection regions ER may include a first connection region ER1 and a second connection region ER2 disposed on opposite (e.g., both) sides of one memory block region CA. The memory block region CA may include memory cells MC. The memory block region CA may include memory cells MC arranged in the first direction (X-direction) and the second direction (Y-direction), word lines WL connected to the memory cells MC and extending in the first direction (X-direction), and bit lines BL connected to the memory cells MC and extending in the second direction (Y-direction). The word lines WL may cross the memory block region CA and may extend into the first and second connecting regions ER1 and ER2.

Each of the memory cells MC may include a cell transistor cTR that may function as a switch and a data storage structure DS that may function as information storage. In a memory such as DRAM, the data storage structure DS may be a cell capacitor capable of storing information.

Each of the memory block regions CA may further include back gate lines BG. Each of the back gate lines BG may be disposed between a pair of word lines WL adjacent to each other, among the word lines WL, in the second direction (Y-direction). Each of the back gate lines BG may be disposed between channel regions of the cell transistors cTR. The back gate lines BG may cross the memory block region CA and extend into the first and second connection regions ER1 and ER2.

Next, referring to FIG. 2B, together with FIGS. 1A, 1B and 2A, each of the sub-word line driver regions SWDR may include sub-word line drivers SWD. The sub-word line drivers SWD may be electrically connected to the word lines WL.

The sub-word line driver SWD may include a PMOS transistor PT, a first NMOS transistor NT1, and a second NMOS transistor NT2. A driving signal PXID may be connected to a source terminal of the PMOS transistor PT, the word line WL may be electrically connected to a drain terminal of the PMOS transistor PT, and a word line enable signal NWEIB may be connected to a gate terminal of the PMOS transistor PT. The PMOS transistor PT may be a pull-up transistor. Precharge voltage corresponding to a back bias voltage VBB2 may be connected to a source terminal of the first NMOS transistor NT1, the word line WL may be electrically connected to a drain terminal of the first NMOS transistor NT1, and the word line enable signal NWEIB may be connected to a gate terminal of the first NMOS transistor NT1. The first NMOS transistor NT1 may be a pull-down transistor. A complementary driving signal PXIB may be connected to a gate terminal of the second NMOS transistor NT2, the precharge voltage corresponding to the back bias voltage VBB2 may be connected to a source terminal of the second NMOS transistor NT2, and the word line WL may be electrically connected to a drain terminal of the second NMOS transistor NT2. The second NMOS transistor NT2 may be a keeping transistor for maintaining the word line WL on a level of a ground voltage when the word line WL is not selected. The second NMOS transistor NT2 may be connected in parallel with the first NMOS transistor NT1. The sub-word line driver SWD may drive the word line WL in response to the word line enable signal NWEIB and the driving signal PXID. The PMOS transistor PT may pull up the word line WL to a level of the driving signal PXID in response to the word line enable signal NWEIB. The first NMOS transistor NT1 may pull down the word line WL to a level of negative voltage VBB2 in response to the word line enable signal NWEIB. The second NMOS transistor NT2, which may be a keeping transistor, may maintain the word line WL at the level of the negative voltage VBB2 when the word line WL is deactivated. To this end, the second NMOS transistor NT2 may switch between a source provided with the negative voltage VBB2 and a drain electrically connected to the word line WL in response to a driving signal PXIB that is complementary to the driving signal PXID. A circuit of the sub-word line drivers SWD described above is an example embodiment, and the circuit of the sub-word line drivers SWD may be implemented in various circuit configurations.

Next, referring to FIG. 2C along with FIGS. 1A, 1B, 2A and 2B, each of the sense amplifier regions SAR may include sense amplifiers SA. The sense amplifier SA may include a plurality of transistors P1_a, P1_b, N1_a, and N1_b. The transistors P1_a, P1_b, N1_a, and N1_b may include P1_a transistor and P1_b transistor, which are PMOS transistors, and N1_a transistor and N1_b transistor, which are NMOS transistors. The P1_a transistor and the P1_b transistor may be referred to as a pair of PMOS transistors, and the N1_a transistor and the N1_b transistor may be referred to as a pair of NMOS transistors. A source of the P1_a transistor and a source of the P1_b transistor may be connected to a first control line LA through a first node ND1_a. A source of the N1_a transistor and a source of the N1_b transistor may be connected to a second control line LAB through a second node ND1_b. The first node ND1_a and the second node ND1_b may be referred to as a first source node and a second source node, respectively. A drain of the P1_a transistor and a drain of the N1_a transistor may be connected to a first bit line BL1, among the bit lines BL, through a first drain node ND1_c. A drain of the P1_b transistor and a drain of the N1_b transistor may be connected to a complementary bit line BL2, among the bit lines BL, through a second drain node ND1_d. The sense amplifier SA may sense an amount of voltage change of the first bit line BL1 and amplify the amount thereof. When the sense amplifier SA performs sensing and amplification operations, internal power voltage may be applied to the first node ND1_a through the first control line LA, and the second node ND1_b may be connected to a ground terminal through the second control line LAB. The sense amplifier SA includes a pair of PMOS transistors and a pair of NMOS transistors, and is implemented in a cross-coupled circuit configuration between transistors, but this is an example embodiment, and the embodiments are not limited thereto. For example, a circuit of the sense amplifier SA may be implemented in various circuit configurations.

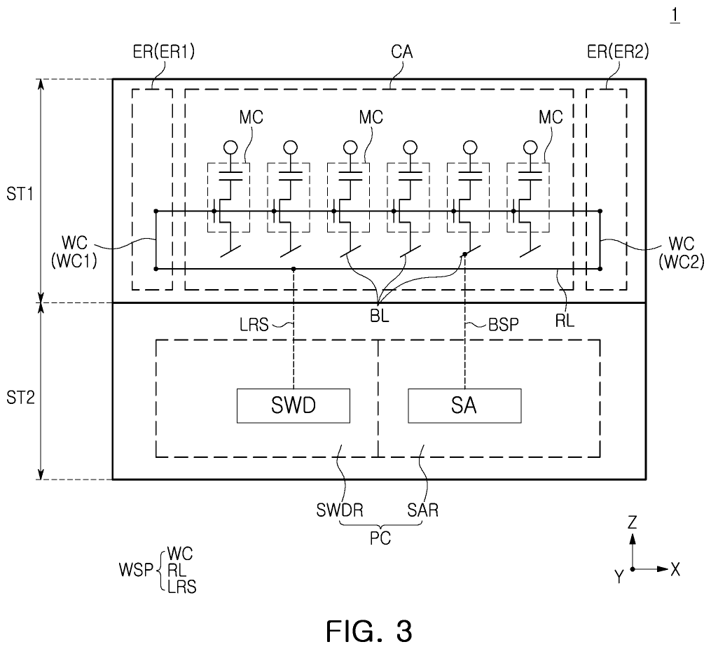

Next, referring to FIG. 3, an electrical connection relationship between one memory block region CA, among the memory block regions CA, and the peripheral circuit region PC vertically overlapping (e.g., vertically overlapped by) the one memory block region CA will be described. FIG. 3 is a view illustrating the electrical connection relationship between the first structure ST1 and the second structure ST2 described above.

Referring to FIG. 3 together with FIGS. 1A to 2C, as described in FIG. 2A, the first connection region ER1 and the second connection region ER2 may be disposed on opposite (e.g., both) sides of the one memory block region CA. Accordingly, the first structure ST1 may include the first connection region ER1, the memory block region CA and the second connection region ER2, sequentially arranged in the first direction (X-direction).

The first structure ST1 may include the memory cells MC, the word line WL, and the bit lines BL described above. The memory cells MC may be disposed in the memory block region CA, and may be arranged sequentially in the first direction (X-direction). The word line WL may cross the memory block region CA and extend into the first and second connection regions ER1 and ER2. The word line WL may be electrically connected to the memory cells MC. The bit lines BL may be electrically connected to the memory cells MC.

The second structure ST2 may include a peripheral circuit region PC including the sub-word line driver region SWDR and the sense amplifier region SAR described above.

In the vertical direction (Z-direction), at least a portion of the peripheral circuit region PC may overlap (e.g., be overlapped by) the memory block region CA. According to an example embodiment, a portion of the peripheral circuit region PC may vertically overlap (e.g., be vertically overlapped by) at least one of the first and second connection regions ER1 and ER2. The second structure ST2 may include the sub-word line driver SWD disposed in the sub-word line driver region SWDR, and the sense amplifier SA disposed in the sense amplifier region SAR, described above.

The first and second structures ST1 and ST2 may further include a word line signal path WSP electrically connecting the word line WL and the sub-word line driver SWD.

The word line signal path WSP may include routing contacts WC disposed in the connection regions ER and connected to the word line WL and a routing interconnection line RL disposed at a height level different from the word line WL and connected to the routing contacts WC, and a lower routing structure LRS electrically connecting the routing interconnection line RL and the sub-word line driver SWD.

The routing interconnection line RL may cross the memory block region CA and extend into the first and second connection regions ER1 and ER2.

A portion/region in which the lower routing structure LRS and the routing interconnection line RL are connected/coupled (e.g., intersect and/or contact each other) may be disposed below the memory cells MC.

The routing contacts WC may include at least one first routing contact WC1 connected to the word line WL in the first connection region ER1, and at least one second routing contact WC2 connected to the word line WL in the second connection region ER2. In some embodiments, the at least one first routing contact WC1 comprises two or more first routing contacts WC1 that are spaced apart from each other, and the at least one second routing contact WC2 comprises two or more second routing contacts WC2 that are spaced apart from each other. The routing contacts WC may also be referred to as word line contacts or gate contacts.

The first structure ST1 may include an upper region of the lower routing structure LRS, the routing contacts WC, and the routing interconnection line RL, and the second structure ST2 may include a lower region of the lower routing structure LRS.

The bit lines BL may cross the memory block region CA in a direction, intersecting the word line WL, for example, in the second direction (Y-direction). The bit lines BL may be electrically connected to the memory cells MC.

The first and second structures ST1 and ST2 may further include bit line signal paths BSP electrically connecting the bit lines BL and the sense amplifiers SA in the sense amplifier region SAR. For example, the bit line signal paths BSP may include a first bit line signal path BSP disposed between a first bit line BL electrically connected to one memory cell MC of the memory cells MC, among the bit lines BL, and the sense amplifier SA. Portions in which the bit line signal paths BSP and the bit lines BL are connected may be disposed below the memory cells MC.

The first structure ST1 may include upper regions of the bit line signal paths BSP, and the second structure ST2 may include lower regions of the bit line signal paths BSP.

The sub-word line driver SWD may be electrically connected to the word line WL through the word line signal path WSP. The voltage applied to the word line WL from the sub-word line driver SWD may be applied to the word line WL in the memory block region CA through the first routing contact WC1 of the first connection region ER1 and the second routing contact WC2 of the second connection region ER2.

In example embodiments, through the first and second connection regions ER1 and ER2 disposed on opposite (e.g., both) sides of the memory block region CA, since voltage may be applied to the word line WL in the memory block region CA, Resistive-Capacitive delay (RC delay) may be reduced. For example, through the first and second connection regions ER1 and ER2, voltage may be applied to the word line WL in the memory block region CA, so that the RC delay caused by parasitic capacitance between the word lines WL adjacent to each other in the memory block region CA may be reduced. Accordingly, the operating speed of the semiconductor device 1 may be improved.

Additionally, through the first and second connection regions ER1 and ER2, voltage may be applied to the word line WL in the memory block region CA, and thus, the charge sharing time in a DRAM memory may be reduced, so that performance of the semiconductor device 1 may be improved.

Additionally, even if a phenomenon in which a portion of the word line WL is cut off or a portion of the word line WL is thinned occurs, which may occur as a width of the word line WL is reduced due to the trend toward high integration, through the first and second connection regions ER1 and ER2, and thus, voltage may be applied from opposite (e.g., both) sides of the word line WL, it may be possible to reduce/prevent defects caused by the phenomenon in which a portion of the word line WL is cut off or a portion of the word line WL is thinned. That is, even if a portion of the word line WL is cut off or a portion of the word line WL is thinned, the word line WL may operate normally.

Additionally, through the first and second connection regions ER1 and ER2, voltage may be applied to the word line WL in the memory block region CA, so that it may be possible to reduce/minimize a time difference between a memory cell MC to which a word line voltage is applied most quickly and a memory cell MC to which the word line voltage is applied most recently, among the memory cells MC connected to the word line WL. Accordingly, the operating speed and performance of the semiconductor device 1 may be improved.

Additionally, through the first and second connection regions ER1 and ER2, voltage may be applied to the word line WL in the memory block region CA, so that it may be possible to reduce charge loss in the data storage structure DS, which may be a capacitor, due to an occurrence of a phenomenon in which the voltage applied to the word line WL fluctuates, that is, an occurrence of word line fluctuation (WL fluctuation). In this manner, the charge loss in the data storage structure DS may be reduced, thereby improving the performance of the semiconductor device 1.

TABLE 1

| | Sub-word Line | | |
|---|---|---|---|
| | Driver Driving | Word Line | |
| | Capability | Fluctuation | Charge Loss |
| First Sample | Default | A mV | E % |
| Second Sample | Default | B mV | F % |
| Third Sample | m times | C mV | G % |
| Fourth Sample | n times | D mV | H % |

In Table 1, the first sample, the second sample, the third sample, and the fourth sample may be samples according to an example embodiment of the present disclosure.

The first sample may be a first reference sample that omits the second routing contact WC2 from the word line signal path WSP of FIG. 3 and is electrically connected to the sub-word line driver SWD and the word line WL through the first routing contact WC1.

The second sample may be a second reference sample electrically connected to the sub-word line driver SWD and the word line WL through the first and second routing contacts WC1 and WC2, as illustrated in FIG. 3.

The third sample and the fourth sample may be samples that increase driving capability of the sub-word line driver SWD from the second sample. The third sample may be a sample in which the driving capability of the sub-word line driver SWD is increased by m times from the second sample, and the fourth sample may be a sample in which the driving capability of the sub-word line driver SWD is increased by n times from the second sample. For example, the third sample may have a sub-word line driver having a driving capability approximately 4 times greater than that of the sub-word line driver SWD of the second sample, and the fourth sample may have a sub-word line driver (SWD) with a driving capability approximately 8 times greater than that of the sub-word line driver (SWD) of the second sample.

In Table 1 above, B millivolts (mV) may be less than A mV. For example, B mV may be 40% to about 60% of A mV. C mV can be less than B mV. D mV can be less than C mV. E % may be less than F %. For example, E % may be ½ to ⅕ times the F %. F % may be less than E %. For example, E % may be ½ to ⅛ times the F %. G % may be less than H %

From Table 1 above, in terms of word line fluctuation, it may be seen that the word line fluctuation is small (e.g., decreasing) in the order of the first sample, second sample, third sample, and fourth sample.

In terms of word line fluctuation, it may be seen that the performance of the semiconductor device of the second sample is improved as compared to the performance of the semiconductor device of the first sample. Accordingly, it may be seen that performance of the semiconductor device of the second sample electrically connecting the sub-word line driver SWD and the word line WL through the first and second routing contacts WC1 and WC2 may be further improved than that of the semiconductor device of the first sample in which the second routing contact WC2 is omitted from the word line signal path WSP, and the sub-word line driver SWD and the word line WL are electrically connected through the first routing contact WC1.

In terms of word line fluctuation, like the third sample and the fourth sample, it may be seen that the performance of the semiconductor device improves as the driving capability of the sub-word line driver SWD increases.

In terms of charge loss of the data storage structure DS, it may be seen that the performance of the semiconductor device of the second sample is improved as compared to the performance of the semiconductor device of the first sample.

In terms of charge loss of the data storage structure DS, like the third sample and the fourth sample, it may be seen that the performance of the semiconductor device is improved as the driving capability of the sub-word line driver SWD increases.

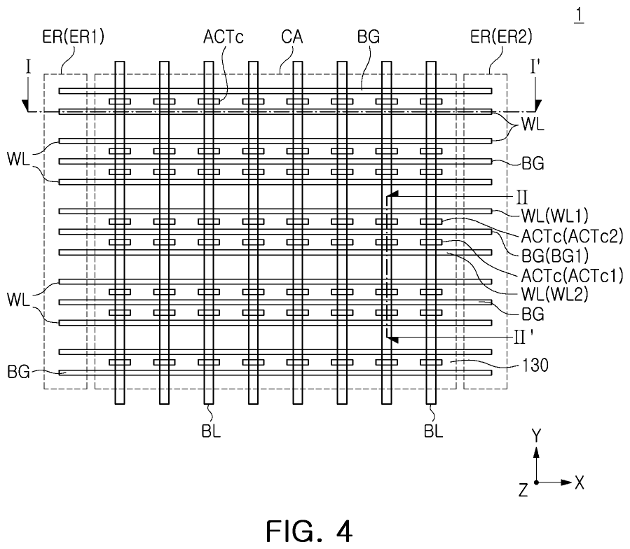

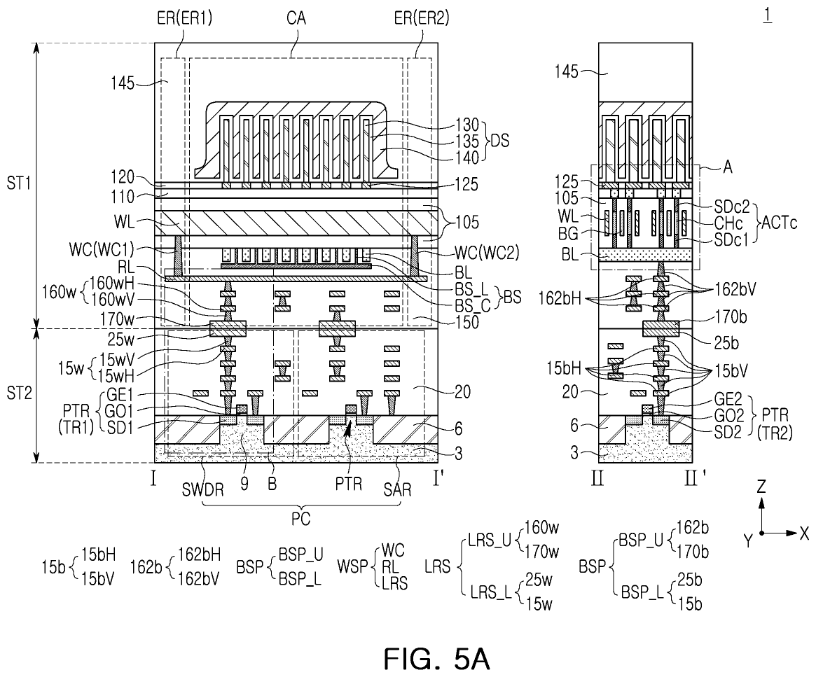

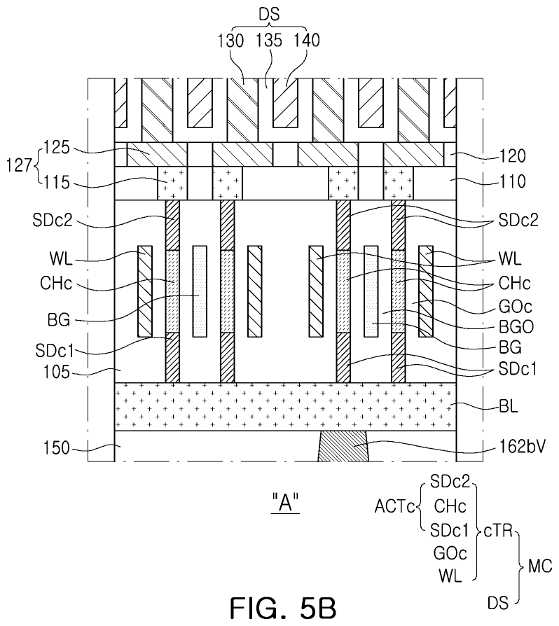

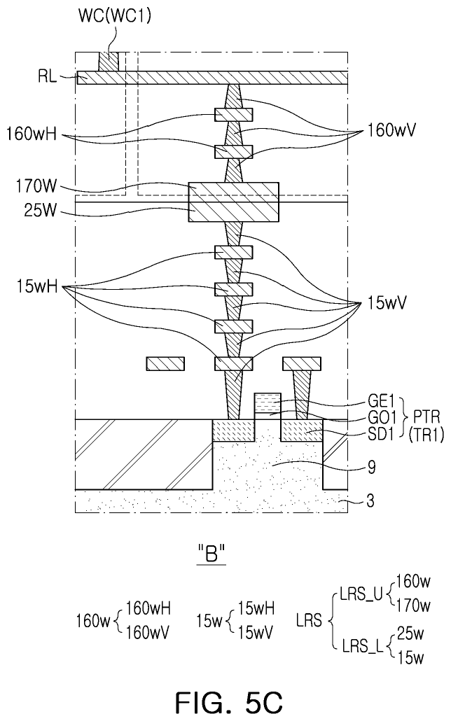

Next, referring to FIGS. 4, 5A, 5B, and 5C, a planar shape and a cross-sectional shape of the semiconductor device 1 described above will be described. FIG. 4 is a plan view schematically illustrating the first connection region ER1, the memory block region CA, and the second connection region ER2 in FIG. 3, FIG. 5A is a cross-sectional view illustrating regions taken along lines I-I′ and II-II′ of FIG. 4, FIG. 5B is a partially enlarged view of a region indicated by ‘A’ in FIG. 5A, and FIG. 5C is a partially enlarged view of a region indicated by ‘B’ in FIG. 5A.

Referring to FIGS. 1A to 3 together with FIGS. 4, 5A, 5B and 5C, the first structure ST1 may further include active patterns ACTc. The active patterns ACTc may include a material that may be used as a channel for a transistor, for example, a semiconductor material. For example, each of the active patterns ACTc may include at least one of a silicon layer, an oxide semiconductor layer, and a two-dimensional material layer having semiconductor properties, which may be used as a channel region of a transistor. For example, each of the active patterns ACTc may include single crystal silicon or polysilicon. The active patterns ACTc may be arranged in the first direction (X-direction) and the second direction (Y-direction). Each of the active patterns ACTc may have a bar shape extending in the first direction (X-direction).

Each of the active patterns ACTc may include a first source/drain region SDc1, a second source/drain region SDc2 disposed at a higher level than the first source/drain region SDc1, and a channel region CHc between, in the vertical direction Z, the first and second source/drain regions SDc1 and SDc2.

Each of the cell transistors cTR may include a first source/drain region SDc1, a second source/drain region SDc2 disposed at a higher level than the first source/drain region SDc1, a channel region CHc between the first and second source/drain regions SDc1 and SDc2, a gate dielectric layer GOc in contact with a side surface of the channel region CHc, and the word line WL in contact with the gate dielectric layer GOc. In the word line WL, a portion facing the channel region CHc (and/or in contact with the gate dielectric layer GOc) may be a gate electrode. Each of the word lines WL may have a vertical length greater than a width thereof in the second direction (Y-direction). Here, the vertical length may be the length from a lower surface to an upper surface of the word line WL. The word lines WL may have side surfaces facing the side surfaces of the active patterns ACTc.

In a plane as illustrated in FIG. 4, the word lines WL may include a first word line WL1 and a second word line WL2 adjacent to each other in the second direction (Y-direction), the active patterns ACTc may include a first active pattern ACTc1 adjacent to the first word line WL1 and a second active pattern ACTc2 adjacent to the second word line WL2, between the first and second word lines WL1 and WL2, and the back gate lines BG (see FIGS. 2, 4, 5A, and 5B) may include a first back gate line BG1 disposed between the first and second word lines WL1 and WL2 and passing between the first active pattern ACTc1 and the second active pattern ACTc2. The back gate lines BG may be back gate electrodes.

The first structure ST1 may include back gate dielectric layers BGO between the back gate lines BG and the active patterns ACTc. The back gate lines BG may have side surfaces facing side surfaces of the channel regions CHc of the active patterns ACTc. Each of the active patterns ACTc may be disposed between one word line WL and one back gate line BG adjacent to each other.

The back gate lines BG may control charges accumulated in the channel regions CHc. The channel regions CHc may be floating bodies disposed between the first and second source/drain regions SDc1 and SDc2, and the back gate lines BG may suppress or prevent the performance of the cell transistors cTR from being deteriorated due to a floating body effect and improve the performance of the cell transistors cTR. For example, during operating of the cell transistors cTR, the back gate lines BG may minimize or prevent changes in a threshold voltage of the cell transistors cTR by accumulating charges, for example, holes, in a floating body of the channel regions CHc.

The word lines WL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or a combination thereof, but the present disclosure is not limited thereto. Each of the word lines WL may include a single layer or multiple layers of the above-described conductive materials. The back gate lines BG may include at least one conductive material. For example, each of the back gate lines BG may be formed of doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, or a combination thereof, but the present disclosure is not limited thereto. Each of the back gate lines BG may include a single layer or multiple layers of the above-described materials.

The first structure ST1 may further include contact structures 127 connected to the second source/drain regions SDc2. Each of the contact structures 127 may include a plug portion 115 in contact with the active pattern ACTc and a pad portion 125 on the plug portion 115.

The data storage structures DS may include first electrodes 130 disposed on the pad portions 125 and extending in the vertical direction (Z-direction), a second electrode 140 on a side surface and an upper surface of each of the first electrodes 130, and a dielectric layer 135 between the first electrodes 130 and the second electrode 140. The data storage structures DS may be capacitors capable of storing information.

The first electrodes 130 may be connected to the pad portions 125 of the contact structures 127. The first electrodes 130 may be electrically connected to the second source/drain regions SDc2 through the contact structures 127. Accordingly, the cell transistors cTR may be electrically connected to the data storage structures DS through the contact structures 127.

The data storage structures DS may be cell capacitors capable of storing information in a memory such as DRAM, but the example embodiments are not limited thereto. For example, the data storage structures DS may be information storage structures of MRAM or information storage structures of FeRAM.

The bit lines BL may be connected to the active patterns ACTc below the active patterns ACTc. For example, the bit lines BL may be electrically connected to the first source/drain regions SDc1 of the active patterns ACTc. Accordingly, the bit lines BL may be electrically connected to the cell transistors cTR.

The first structure ST1 may further include a shield conductive structure BS including line portions BS_L alternately arranged with the bit lines BL and a connection portion BS_C connecting the line portions BS_L. The shield conductive structure BS may screen capacitive coupling between the bit lines BL. For example, the shield conductive structure BS may reduce or block parasitic capacitance between the bit lines BL, thereby reducing/minimizing resistive-capacitive delay RC of the bit lines BL.

The first structure ST1 may include a first insulating structure 150, a second insulating structure 105 on the first insulating structure 150, a third insulating layer 110 on the second insulating structure 105, a fourth insulating layer 120 on the third insulating layer 110, and an upper insulating structure 145 on the fourth insulating layer 120. The bit lines BL may be disposed in the first insulating structure 150. A structure including the active patterns ACTc, the word lines WL, the back gate lines BG, the gate dielectric layers GOc, and the back gate dielectric layers BGO may penetrate through the second insulating structure 105. The contact structures 127 may penetrate through the third and fourth insulating layers 110 and 120. The upper insulating structure 145 may be disposed on the fourth insulating layer 120 and the data storage structure DS.

The first structure ST1 may include conductive structures WC, RL, 160w, 170w, 170b and 162b disposed below the word lines WL and the bit lines BL.

The conductive structures may include the routing contacts WC disposed below the word lines WL and disposed in the connection regions ER, routing interconnection lines RL connected to the routing contacts WC and disposed at a lower level than the bit lines BL, a word line lower interconnection structure 160w electrically connected to the routing interconnection lines RL below the routing interconnection lines RL, a bit line lower interconnection structure 162b electrically connected to the bit lines BL below the bit lines BL, and first bonding pads 170w and 170b connected to the word line lower interconnection structure 160w and the bit line lower interconnection structure 162b.

The word line lower interconnection structures 160w may include horizontal portions 160wH disposed at different levels and vertical portions 160wV connected to the horizontal portions 160wH. Here, the horizontal portions 160wH may be interconnection lines or pads, and the vertical portions 160wV may be conductive vias. The bit line lower interconnection structure 162b may include horizontal portions 162bH disposed at different levels and vertical portions 162bV connected to the horizontal portions 162bH. Here, the horizontal portions 162wH may be interconnection lines or pads, and the vertical portions 162bV may be conductive vias.

The first bonding pads 170w and 170b may have lower surfaces coplanar with a lower surface of the first insulating structure 150. The first bonding pads 170w and 170b may include first word line bonding pads 170w connected to the word line lower interconnection structure 160w, and first bit line bonding pads 170b connected to the bit line lower interconnection structure 162b.

The second structure ST2 may further include a substrate 3 and a device isolation region 6 defining active regions 9 on the substrate 3. The substrate 3 may be a semiconductor substrate. The second structure ST2 may further include peripheral transistors PTR and peripheral interconnection structures 15w and 15b disposed on the substrate 3.

The peripheral transistors PTR may include the transistors PT, NT1 and NT2 of the sub-word line driver SWD (see FIG. 2B) and the transistors P1_a, P1_b, N1_a and N1_b of the sense amplifier SA (see FIG. 2C).

In example embodiments, the transistors PT, NT1 and NT2 of the sub-word line driver SWD (see FIG. 2B) may be disposed in the sub-word line driver region SWDR, and the transistors P1_a, P1_b, N1_a, and N1_b of the sense amplifier SA (FIG. 2C) may be disposed in the sense amplifier region SAR. As an example, in the drawings, the peripheral transistors PTR are illustrated as a first peripheral transistor TR1, which may be one of the transistors PT, NT1 and NT2 of the sub-word line driver SWD (see FIG. 2B), and a second peripheral transistor TR2, which may be one of the transistors P1_a, P1_b, N1_a, and N1_b of the sense amplifier SA (See FIG. 2C).

The first peripheral transistor TR1 may include first peripheral gate structures GE1 and GO1 disposed on the active region 9 disposed in the sub-word line driver region SWDR, and first peripheral source/drain regions SD1 disposed in the active region 9 disposed on opposite (e.g., both) sides of the first peripheral gate structures GE1 and GO1. The first peripheral gate structures GE1 and GO1 may include a first peripheral gate dielectric layer GO1 and a first peripheral gate electrode GE1, which are sequentially stacked. The second peripheral transistor TR2 may include second peripheral gate structures GE2 and GO2 disposed on the active region 9 disposed in the sense amplifier region SAR, and second peripheral source/drain regions SD2 disposed in the active region 9 disposed on opposite (e.g., both) sides of the second gate structures GE2 and GO2. The second peripheral gate structures GE2 and GO2 may include a second peripheral gate dielectric layer GO2 and a second peripheral gate electrode GE2, which are sequentially stacked.

The peripheral interconnection structures 15w and 15b may include a word line peripheral interconnection structure 15w and a bit line peripheral interconnection structure 15b.

The word line peripheral interconnection structures 15w may include horizontal portions 15wH disposed at different levels and vertical portions 15wV connected to the horizontal portions 15wH. Here, the horizontal portions 15wH may be interconnection lines or pads, and the vertical portions 15wV may be conductive vias. The bit line peripheral interconnection structures 15b may include horizontal portions 15bH disposed at different levels, and vertical portions 15bV connected to the horizontal portions 15bH. Here, the horizontal portions 15wH may be interconnection lines or pads, and the vertical portions 15bV may be conductive vias.

The number of horizontal portions 15wH of the word line peripheral interconnection structures 15w may be greater than the number of horizontal portions 160wH of the word line lower interconnection structures 160w. The number of horizontal portions 15bH of the bit line peripheral interconnection structures 15b may be greater than the number of horizontal portions 162bH of the bit line lower interconnection structure 162b. The number of horizontal portions 115wH of the word line peripheral interconnection structures 15w may be the same as the number of horizontal portions 15bH of the bit line peripheral interconnection structures 15b.

The second structure ST2 may include a lower insulating structure 20 disposed on the substrate 3 and covering the peripheral transistors PTR and the peripheral interconnection structures 15w and 15b, and second bonding pads 25w and 25b having upper surfaces coplanar with an upper surface of the lower insulating structure 20. The second bonding pads 25w and 25b may include second word line bonding pads 25w connected to the word line peripheral interconnection structure 15w, and second bit line bonding pads 25b connected to the bit line peripheral interconnection structure 15b.

The first bonding pads 170w and 170b and the second bonding pads 25w and 25b may include the same metal material that may be bonded to each other. For example, the first bonding pads 170w and 170b and the second bonding pads 25w and 25b may include copper.

Lower surfaces of the first bonding pads 170w and 170b may be in direct contact with and bonded to the upper surfaces of the second bonding pads 25w and 25b, and the lower surface of the first insulating structure 150 may be in direct contact with and bonded to the upper surface of the lower insulating structure 20. Upper surfaces of the second word line bonding pads 25w may be in contact with and bonded to upper surfaces of the first word line bonding pads 170w, and upper surfaces of the second bit line bonding pads 25b may be in contact with and bonded to lower surfaces of the first bit line bonding pads 170b.

As described in FIG. 3, the first and second structures ST1 and ST2 may include the word line signal path WSP and the bit line signal path BSP.

Hereinafter, the description will focus on one word line WL, one word line signal path WSP, and one bit line signal path BSP.

The bit line signal path BSP connected to the bit line BL may include a first bit line interconnection structure BSP_U disposed in the first structure ST1, and a second bit line interconnection structure BSP_L disposed in the second structure ST2. The first bit line interconnection structure BSP_U may include the lower bit line interconnection structure 162b and the first bit line bonding pad 170b. The first bit line interconnection structure BSP_U may include the bit line peripheral interconnection structure 15b and the second bit line bonding pad 25b.

The word line signal path WSP connected to the word line WL may include the routing contacts WC, the routing interconnection line RL, and the lower routing structure LRS.

The routing contacts WC may be in contact with and connected to the word line WL, below the word line WL. The word line WL may be disposed at a higher level than the bit line BL, and upper surfaces of the routing contacts WC may be disposed at a higher level than the bit line BL and may be in contact with a lower surface of the word line WL. Lower surfaces of the routing contacts WC may be disposed at a lower level than the bit line BL. The routing contacts WC may include at least one first routing contact WC1 connected to the word line WL in the first connection region ER1, and at least one second routing contact WC2 connected to the word line WL in the second connection region ER2.

The routing interconnection line RL may have a line shape that crosses the memory block region CA in the first direction X and extends into the first and second connection regions ER1 and ER2. The routing interconnection line RL may vertically overlap (e.g., be vertically overlapped by) the word line WL. The routing interconnection line RL may be disposed at a lower level than the bit line BL. In the memory block region CA, the routing interconnection line RL may vertically overlap (e.g., be vertically overlapped by) the memory cells MC. The routing interconnection line RL may be in contact with and connected to the at least one first routing contact WC1 and the at least one second routing contact WC2 at the same time. For example, a first portion of the routing interconnection line RL may be adjacent the at least one first routing contact WC1, a second portion of the routing interconnection line RL may be adjacent the at least one second routing contact WC2, and the routing interconnection line RL may extend continuously from the first portion to the second portion. An upper surface of the routing interconnection line RL may be in contact with the at least one first routing contact WC1 and the at least one second routing contact WC2.

The lower routing structure LRS may include an upper structure LRS_U disposed in the first structure ST1 and a lower structure LRS_L disposed in the second structure ST2. The upper structure LRS_U may include the word line lower interconnection structure 160w and the first word line bonding pad 170w. The lower structure LRS_L may include the word line peripheral interconnection structure 15w and the second word line bonding pad 25w.

The first peripheral transistor TR1 of the sub-word line driver SWD may be electrically connected to the word line WL through the word line signal path WSP. The voltage applied from the sub-word line driver SWD may be applied to the word line WL in the memory block region CA through the first routing contact WC1 of the first connection region ER1 and the second routing contact WC2 of the second connection region ER2.

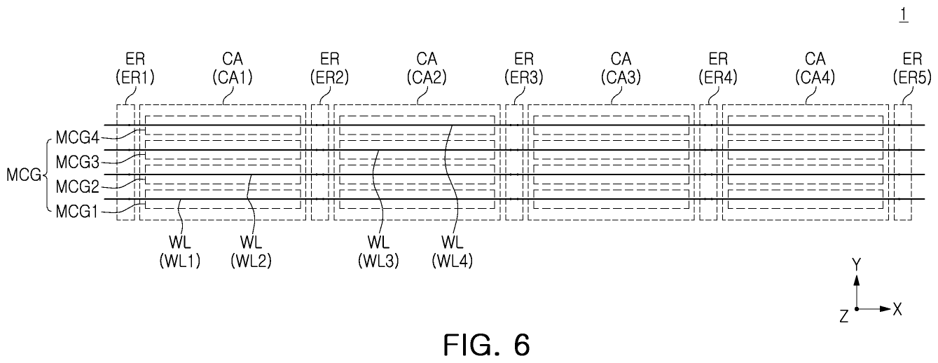

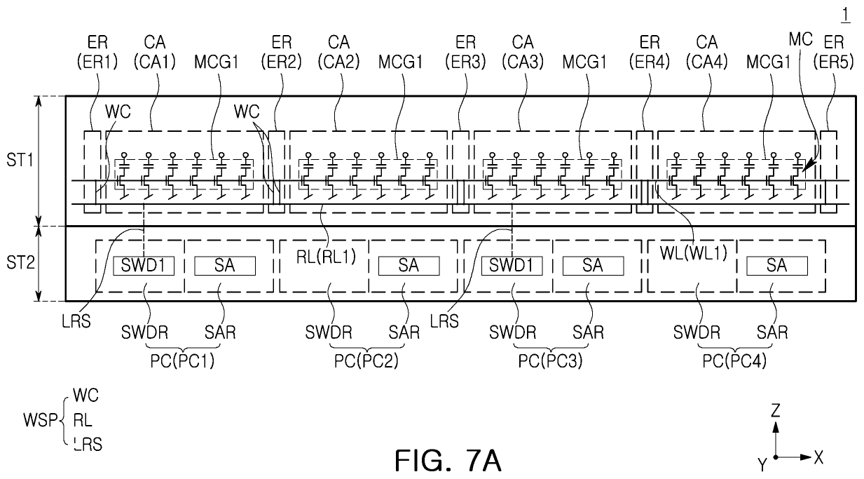

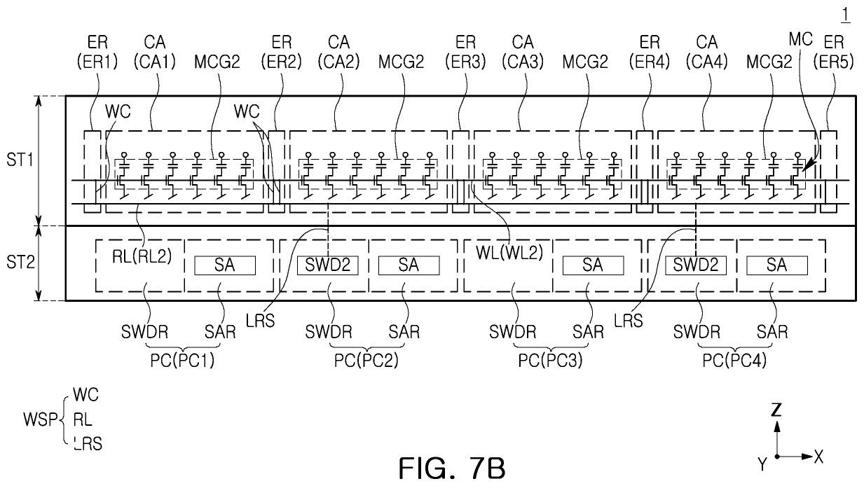

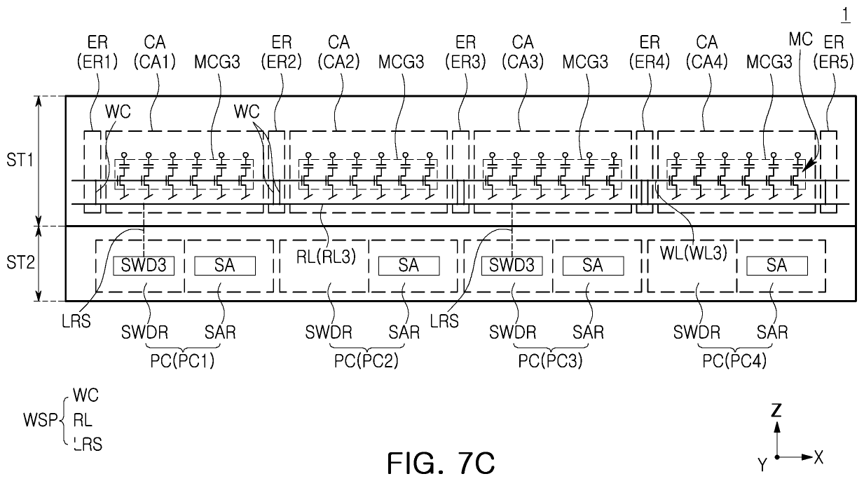

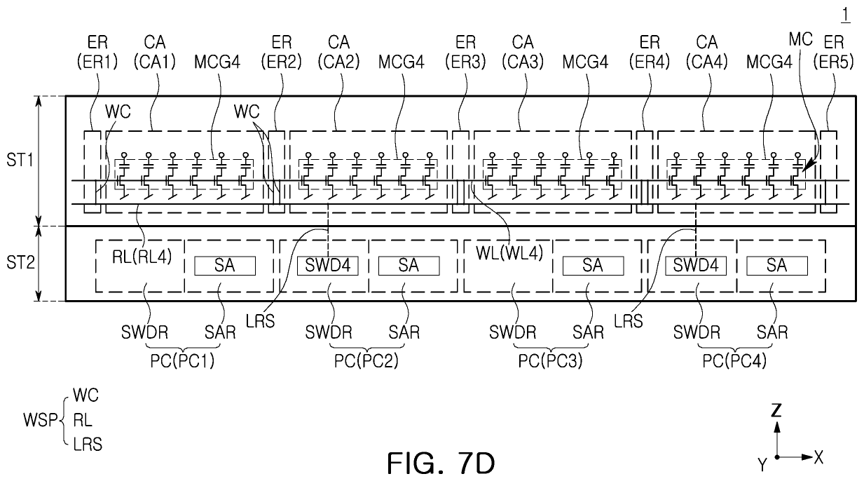

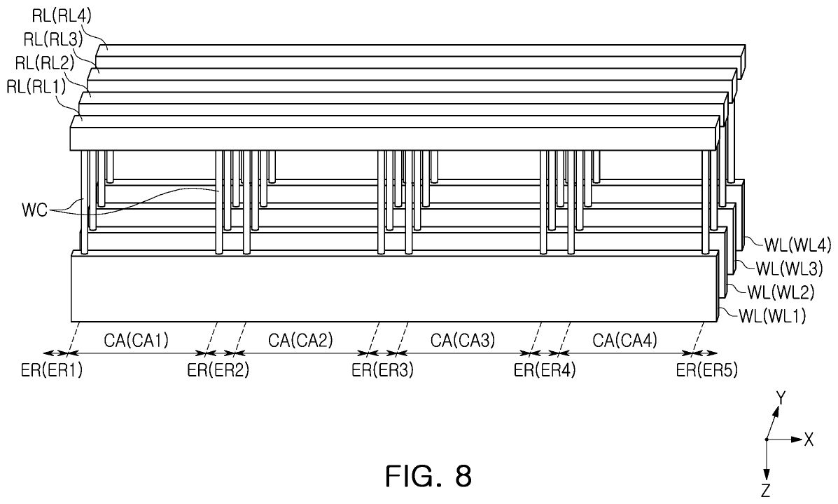

Next, referring to FIGS. 6, 7A, 7B, 7C, 7D and 8, an illustrative example of a semiconductor device according to an example embodiment of the present disclosure will be described. FIG. 6 is a top view illustrating a shape in which the memory block regions CA described above are arranged in plural form in the first direction (X-direction) and the word lines WL are arranged in plural form, FIG. 7A is a conceptual cross-sectional view illustrating an electrical connection relationship of a first word line WL1 among the word lines WL in FIG. 6, FIG. 7B is a conceptual cross-sectional view illustrating an electrical connection relationship of a second word line WL2 among the word lines WL in FIG. 6, FIG. 7C is a conceptual cross-sectional view illustrating an electrical connection relationship of the third word line WL3 among the word lines WL in FIG. 6, FIG. 7D is a conceptual cross-sectional view illustrating an electrical connection relationship of a fourth word line WL4 among the word lines WL in FIG. 6, and FIG. 8 is a schematic perspective view illustrating a relationship between routing interconnection lines RL, routing contacts WC, and word lines WL.

Referring to FIGS. 6, 7A, 7B, 7C, 7D and 8 together with FIGS. 1A to 5B, the memory block regions CA include a first memory block region CA1, a second memory block region CA2, a third memory block region CA3, and a fourth memory block region CA4, which are sequentially arranged in the first direction (X-direction). The connection regions ER may include a first connection region ER1, a second connection region ER2, a third connection region ER3, a fourth connection region ER4, and a fifth connection region ER5, which are sequentially arranged in the first direction (X-direction). The first memory block region CA1 may be disposed between the first connection region ER1 and the second connection region ER2. The second memory block region CA2 may be disposed between the second connection region ER2 and the third connection region ER3. The third memory block region CA3 may be disposed between the third connection region ER3 and the fourth connection region ER4. The fourth memory block region CA4 may be disposed between the fourth connection region ER4 and the fifth connection region ER5.

In one example, the word lines WL may cross the memory block regions CA and the intermediate connection regions ER between the first and second edge connection regions ERe1 and ERe2, and may extend into the first and second edge connection regions ERe1 and ERe2.

The word lines WL may include a first word line WL1, a second word line WL2, a third word line WL3, and a fourth word line WL4, which are arranged sequentially in the second direction (Y-direction). The first and third word lines WL1 and WL3 may be odd-numbered word lines, and the second and fourth word lines WL2 and WL4 may be even-numbered word lines.

In one example, each of the word lines WL may continuously and seamlessly cross the first to fourth memory block regions CA1, CA2, CA3 and CA4 and the first to fifth connection regions ER1, ER2, ER3, ER4 and ER5. For example, the first word line WL may continuously and seamlessly cross the first to fourth memory block regions CA1, CA2, CA3 and CA4 and the first to fifth connection regions ER1, ER2, ER3, ER4 and ER5.

Memory cell groups MCG may be disposed in each of the memory block regions CA. Each of the memory cell groups MCG may include memory cells MC regularly arranged in the first direction (X-direction). Each of the memory cell groups MCG may include memory cells MC arranged at regular intervals in the first direction (X-direction).

The memory cell groups MCG may include a first memory cell group MCG1 connected to the first word line WL1, a second memory cell group MCG2 connected to the second word line WL2, a third memory cell group MCG3 connected to the third word line WL3, and a fourth memory cell group MCG4 connected to the fourth word line WL4.

The peripheral circuit regions PC may include a first peripheral circuit region PC1, a second peripheral circuit region PC2, a third peripheral circuit region PC3, and a fourth peripheral circuit region PC4, which are sequentially arranged in the first direction (X-direction).

The first peripheral circuit region PC1 may vertically overlap the first memory block region CA1, the second peripheral circuit region PC2 may vertically overlap the second memory block region CA2, the third peripheral circuit region PC3 may vertically overlap the third memory block region CA3, and the fourth peripheral circuit region PC4 may vertically overlap the fourth memory block region CA4.

As described above, each of the peripheral circuit regions PC may include the sub-word line driver region SWDR and the sense amplifier region SAR.

The sense amplifier regions SAR may include the sense amplifiers SA.

Odd-numbered word lines WL1 and WL3 and odd-numbered sub-word line drivers SWD1 and SDW3 electrically connected through the word line signal paths WSP may be disposed in the first peripheral circuit region PC1 and the third peripheral circuit region PC3, and even-numbered word lines WL2 and WL4 and even-numbered sub-word line drivers SWD2 and SDW4 electrically connected through the word line signal paths WSP may be disposed in the second peripheral circuit region PC2 and the fourth peripheral circuit region PC4. For example, first sub-word line drivers SWD1 disposed in the first peripheral circuit region PC1 and the third peripheral circuit region PC3 may be electrically connected to the first word line WL1 through the word line signal path WSP, and the third sub-word line drivers SWD3 disposed in the first peripheral circuit region PC1 and the third peripheral circuit region PC3 may be electrically connected to the third word line WL1 through the word line signal path WSP. Second sub-word line drivers SWD2 disposed in the second peripheral circuit region PC2 and the fourth peripheral circuit region PC4 may be electrically connected to the second word line WL2 through the word line signal path WSP, and fourth sub-word line drivers SWD4 disposed in the second peripheral circuit region PC2 and the fourth peripheral circuit region PC4 may be electrically connected to the fourth word line WL4 through the word line signal path WSP.

In one example, in each of the word line signal paths WSP, routing contacts WC disposed in each of the connection regions ER and connected to one word line may be provided in plural form. For example, in the second connection region ER2 between the first memory block region CA1 and the second memory block region CA2, the first word line WL1 may be in contact with and connected to the plurality of routing contacts WC.

The routing interconnection lines RL of the word line signal paths WSP may include a first routing interconnection line RL1 electrically connected to the first word line WL1 and the routing contacts WC, a second routing interconnection line RL1 electrically connected to the second word line WL2 and the routing contacts WC, a third routing interconnection line RL3 electrically connected to the third word line WL3 and the routing contacts WC, and a fourth routing interconnection line RL4 electrically connected to the fourth word line WL4 and the routing contacts WC. The routing interconnection lines RL may vertically overlap (e.g., be vertically overlapped by) the word lines WL.

In one example, each of the routing interconnection lines RL may continuously and seamlessly cross the first to fourth memory block regions CA1, CA2, CA3 and CA4 and the first to fifth connection regions ER1, ER2, ER3, ER4 and ER5. For example, the first routing interconnection line RL1 may continuously and seamlessly cross the first to fourth memory block regions CA1, CA2, CA3 and CA4 and the first to fifth connection regions ER1, ER2, ER3, ER4 and ER5.

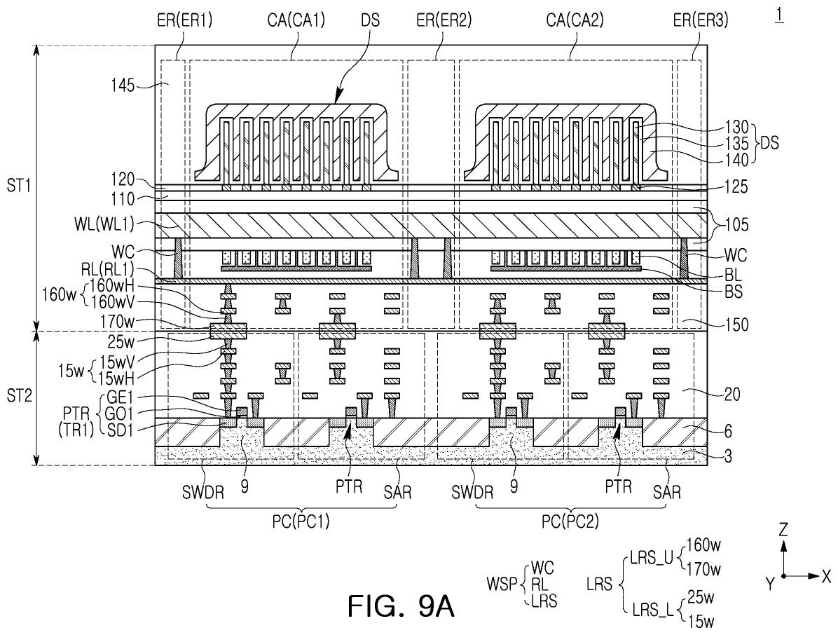

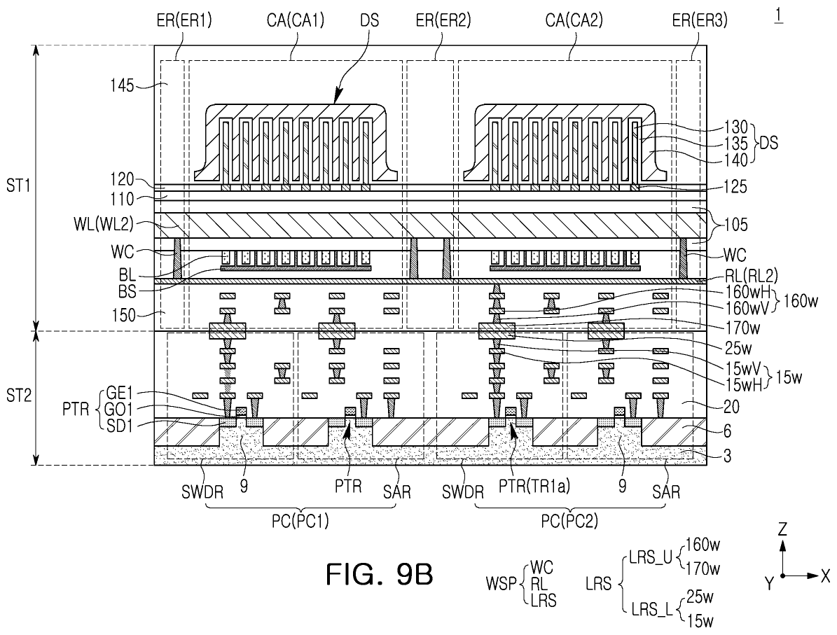

Next, referring to FIGS. 9A and 9B, the cross-sectional structures of the first connection region ER1, the first memory block region CA1, the second connection region ER2, the second memory block region CA2, and the third connection region ER3 sequentially arranged in the first direction (X-direction), and the cross-sectional structures of the first peripheral circuit region PC1 and the second peripheral circuit region PC2 arranged sequentially in the first direction (X-direction), described in FIGS. 6 to 7D, will now be described. In FIGS. 9A and 9B, FIG. 9A is a cross-sectional view centered on the first word line WL1 in FIG. 7A, and FIG. 9B is a cross-sectional view centered on the second word line WL2 in FIG. 7B.

Referring to FIGS. 9A and 9B together with FIGS. 1A to 7D, the cross-sectional structures of the first memory block region CA1 and the first peripheral circuit region PC1 may be the same as the cross-sectional structure taken along line I-I′ in FIG. 5A except for the word line signal path WSP, and the cross-sectional structures of the second memory block region CA2 and the second peripheral circuit region PC2 may be the same as the cross-sectional structure taken along line I-I′ in FIG. 5A except for the word line signal path WSP.

The first sub-word line driver SWD1 as illustrated in FIG. 7A may be disposed in the sub-word line driver region SWDR of the first peripheral circuit region PC1, and the second sub-word line driver SWD2 as illustrated in FIG. 7B may be disposed in the sub-word line driver region SWDR of the second peripheral circuit region PC2.

The first sub-word line driver SWD1 may vertically overlap (e.g., be vertically overlapped by) the first memory block region CA1. For example, the first sub-word line driver SWD1 may vertically overlap (e.g., be vertically overlapped by) the data storage structure DS of the first memory block region CA1. The second sub-word line driver SWD2 may vertically overlap (e.g., be vertically overlapped by) the second memory block region CA2. For example, the second sub-word line driver SWD2 may vertically overlap (e.g., be vertically overlapped by) the data storage structure DS of the second memory block region CA2.

Each of the first and second sub-word line drivers SWD1 and SWD2 may include the transistors PT, NT1 and NT2 described with respect to FIG. 2B.

A first peripheral transistor TR1, which may be one of the transistors PT, NT1 and NT2 (see FIG. 2B) of the first sub-word line driver SWD1, may be disposed in the sub-word line driver region SWDR of the first peripheral circuit region PC1, and a second peripheral transistor TRla, which may be one of the transistors PT, NT1 and NT2 (see FIG. 2B) of the second sub-word line driver SWD2, may be disposed in the sub-word line driver region SWDR of the second peripheral circuit region PC2. The first peripheral transistor TR1 may vertically overlap (e.g., be vertically overlapped by) the data storage structure DS of the first memory block region CA1. The second peripheral transistor TRla may vertically overlap (e.g., be vertically overlapped by) the data storage structure DS of the second memory block region CA2.

In the word line signal path WSP electrically connecting the first word line WL1 and the first peripheral transistor TR1, the lower routing structure LRS may be in contact with and connected to the first routing interconnection line RL1 in the first memory block region CA1.

In the word line signal path WSP electrically connecting the second word line WL2 and the second peripheral transistor TRla, the lower routing structure LRS may be in contact with and connected to the second routing interconnection line RL2 in the second memory block region CA2.

Various modifications of the elements of the example embodiment described above will be described. Various modifications to the elements of the above-described embodiments described below will be explained with a focus on modified or replaced elements. Here, the elements described above may be directly quoted without separate detailed explanation, or the explanation may be omitted. In addition, elements that may be modified or replaced described below are described with reference to the drawings below, but elements that may be modified or replaced may be combined with each other or with the elements described above to form a semiconductor device according to an example embodiment of the present disclosure.

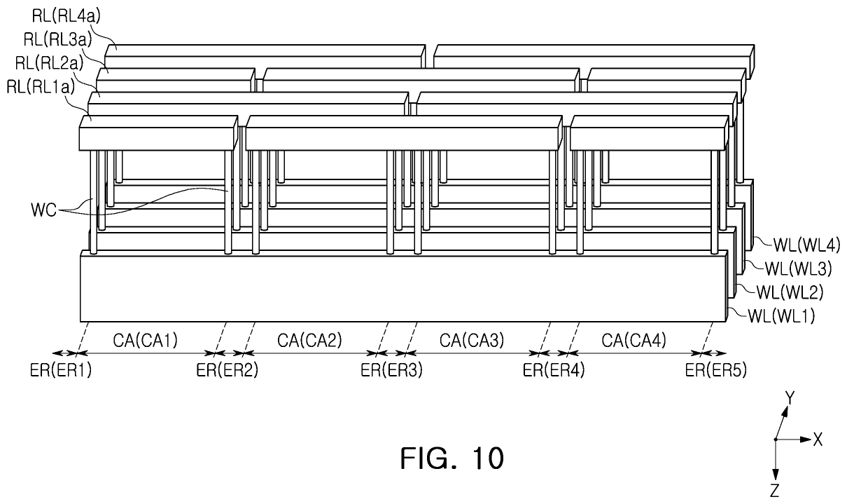

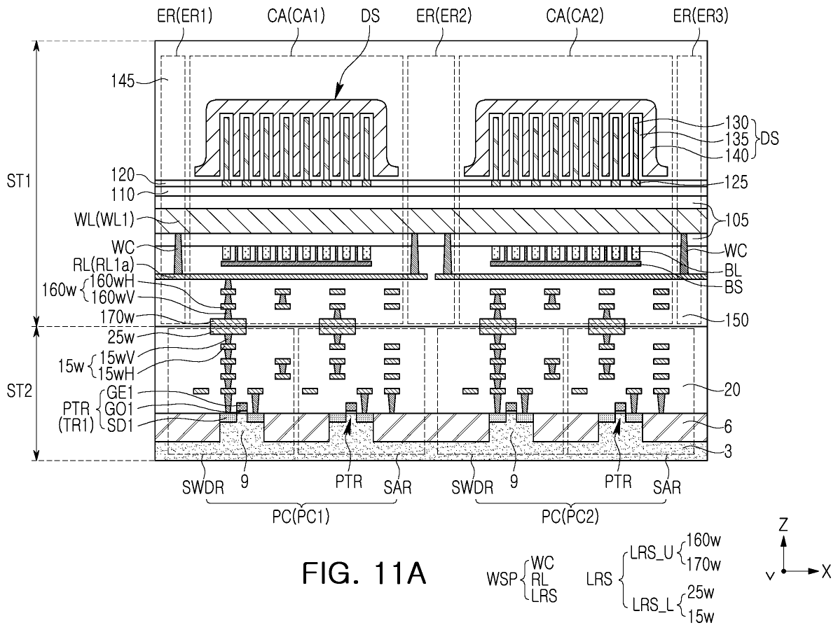

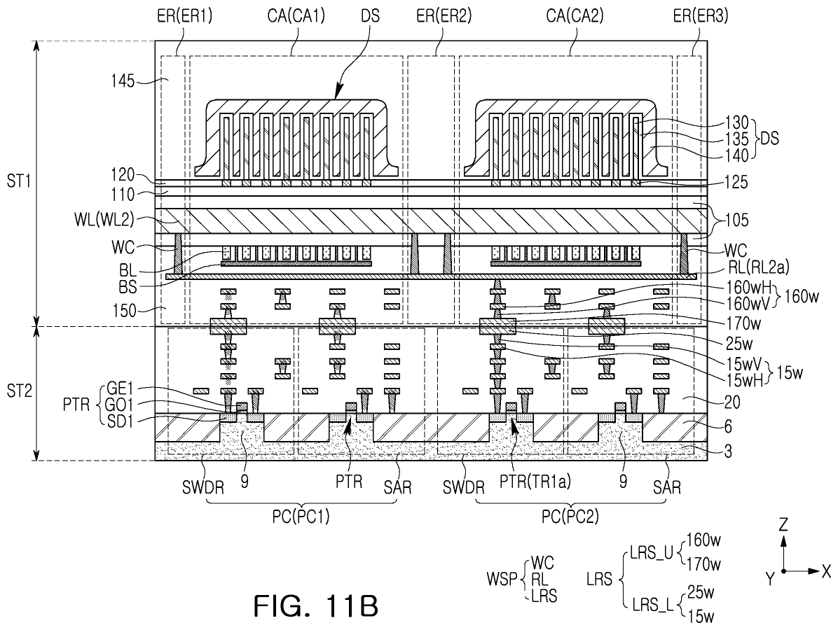

Next, an example of a semiconductor device according to an example embodiment of the present disclosure will be described with reference to FIGS. 10, 11A, and 11B. FIG. 10 is a perspective view illustrating a modified example of the odd-numbered routing interconnection lines RL1 and RL3 and the even-numbered routing interconnection lines RL2 and RL4 described in FIG. 8, FIG. 11A is a cross-sectional view illustrating a modified example of the first routing interconnection line RL1 of FIG. 9A, and FIG. 11B is a cross-sectional view illustrating a modified example of the second routing interconnection line RL2 of FIG. 9B.

Referring to FIGS. 10, 11A and 11B, the odd-numbered routing interconnection lines RL1 and RL3 described in FIG. 8 may be replaced with odd-numbered routing interconnection lines RL1a and RL3a separated from the second connection region ER2 and the second connection region ER4 in the first direction (X-direction).

The first routing interconnection line RL1 in FIG. 8 may be replaced with first routing interconnection lines RL1a separated and spaced apart from each other in the first direction (X-direction). One first routing interconnection line RL1 of the first routing interconnection lines RL1a arranged in the first direction (X-direction) may continuously cross the second memory block region CA2, the third connection region ER3, and the third memory block region CA3, and may extend into the second and fourth connection regions ER2 and ER4. The first routing interconnection line RL1 in FIG. 9A may be replaced with first routing interconnection lines RL1a separated and spaced apart from each other in the second connection region ER2.

The second routing interconnection line RL2 in FIG. 8 may be replaced with second routing interconnection lines RL2a separated and spaced apart from each other in the first direction (X-direction). One second routing interconnection line RL2a of the second routing interconnection lines RL2a arranged in the first direction (X-direction) may continuously cross the first memory block region CA1, the second connection region ER2, and the second memory block region CA2, and may extend into the first and third connection regions ER1 and ER3. The second routing interconnection line RL2 in FIG. 9B may be replaced with second routing interconnection lines RL2a separated from the first and third connection regions ER1 and ER3.

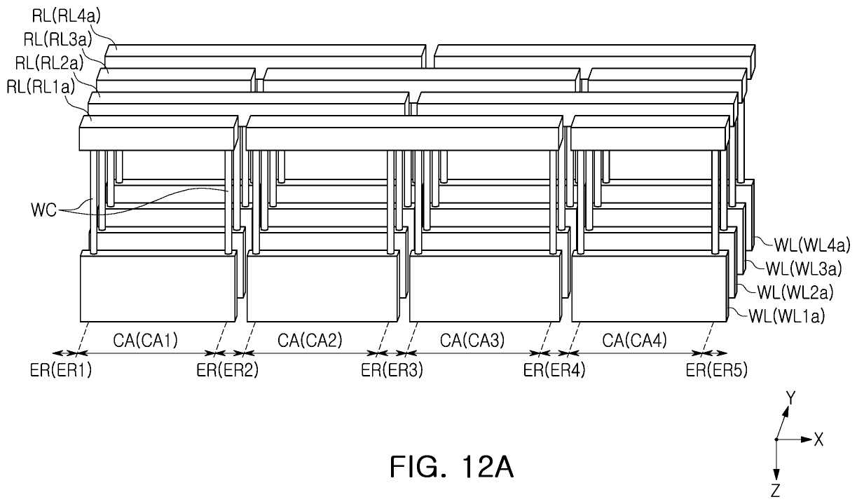

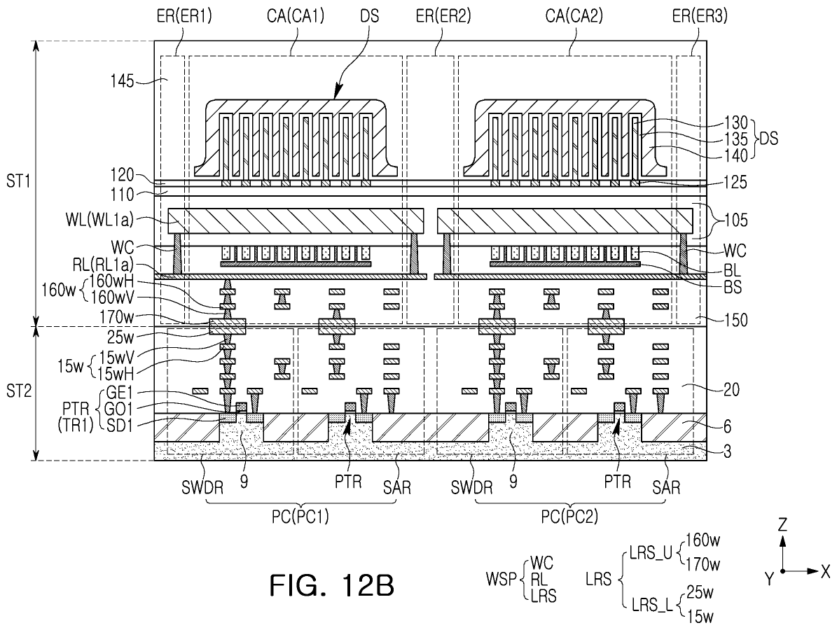

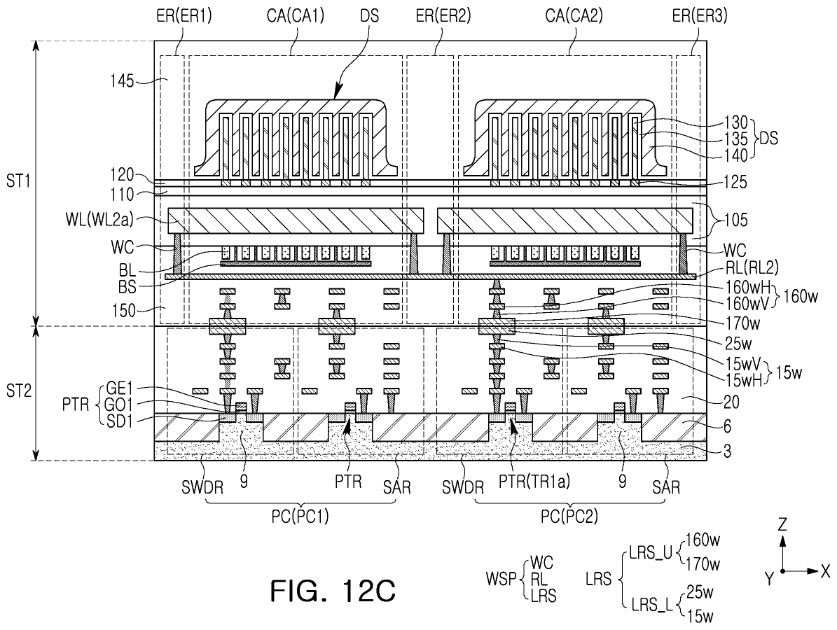

Next, an example of a semiconductor device according to an example embodiment of the present disclosure will be described with reference to FIGS. 12A, 12B, and 12C. FIG. 12A is a perspective view illustrating a modified example of the odd-numbered word lines WL1 and WL3 and the even-numbered word lines WL2 and WL4 in FIG. 10, FIG. 12B is a cross-sectional view illustrating a modified example of the first word line WL1 of FIG. 11A, and FIG. 12C is a cross-sectional view illustrating a modified example of the second word line WL2 of FIG. 11B.

Referring to FIGS. 12A, 12B and 12C, the odd-numbered word lines WL1 and WL3 and the even-numbered word lines WL2 and WL4 in FIG. 10 may be replaced with odd-numbered word lines WL1a and WL3a and even-numbered word lines WL2a and WL4a separated and spaced apart from each other in the connection regions ER. For example, the first word line WL1 in FIGS. 10 and 11A may be replaced with first word lines WL1a separated and spaced from each other in the connection regions ER and sequentially arranged in the first direction (X-direction), and the second word lines WL2 in FIGS. 10 and 11B may be replaced with second word lines WL2a separated and spaced from each other in the connection regions ER and sequentially arranged in the first direction (X-direction).

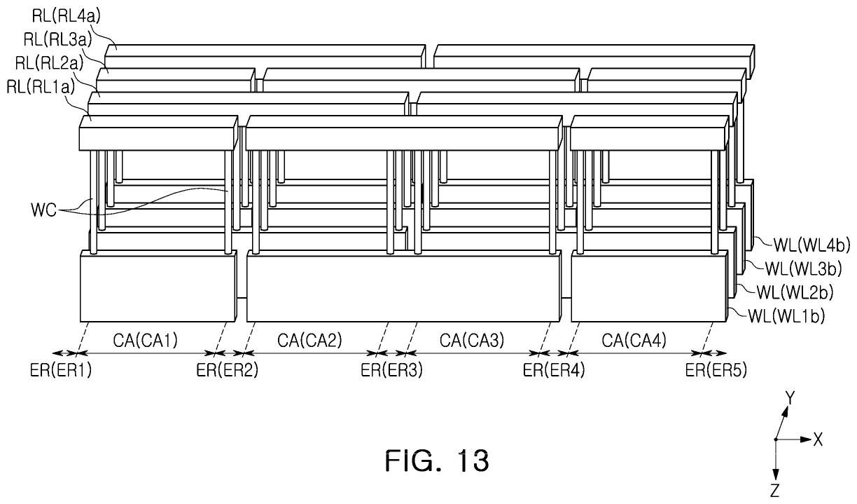

Next, referring to FIG. 13, an example of a semiconductor device according to an example embodiment of the present disclosure will be described. FIG. 13 is a perspective view illustrating a modified example of the odd-numbered word lines WL1 and WL3 and the even-numbered word lines WL2 and WL4 in FIG. 10.

Referring to FIG. 13, the odd-numbered word lines WL1 and WL3 in FIG. 10 may be replaced with odd-numbered word lines WL1b and WL3b separated at the same position as the odd-numbered routing interconnection lines RL1a and RL3a, and the even-numbered word lines WL2 and WL4 in FIG. 10 may be replaced with even-numbered word lines WL2b and WL4b separated at the same position as the even-numbered routing interconnection lines RL2a and RL4a.

The first word line WL1 in FIG. 10 may be replaced with first word lines WL1b separated and spaced apart from each other in the first direction (X-direction). One first word line WL1b of the first word lines WL1b arranged in the first direction (X-direction may continuously cross the second memory block region CA2, the third connection region ER3, and the third memory block region CA3, and may extend into the second and fourth connection regions ER2 and ER4. The first word lines WL1b arranged in the first direction (X-direction) may be separated and spaced from each other in the even-numbered connection regions ER2 and ER4.

The second word line WL2 in FIG. 10 may be replaced with second word lines WL2b separated and spaced apart from each other in the first direction (X-direction). One second word line WL2b of the second word lines WL2b arranged in the first direction (X-direction) may continuously cross the first memory block region CA1, the second connection region ER2, and the second memory block region CA2, and may extend into the first and third connection regions ER1 and ER3. The second word lines WL2b arranged in the first direction (X-direction) may be separated and spaced apart from each other in the odd-numbered connection regions ER1 and ER3.

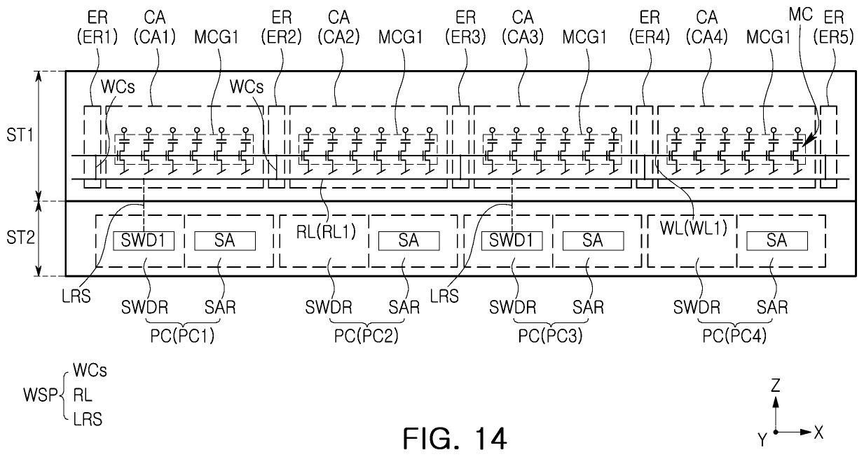

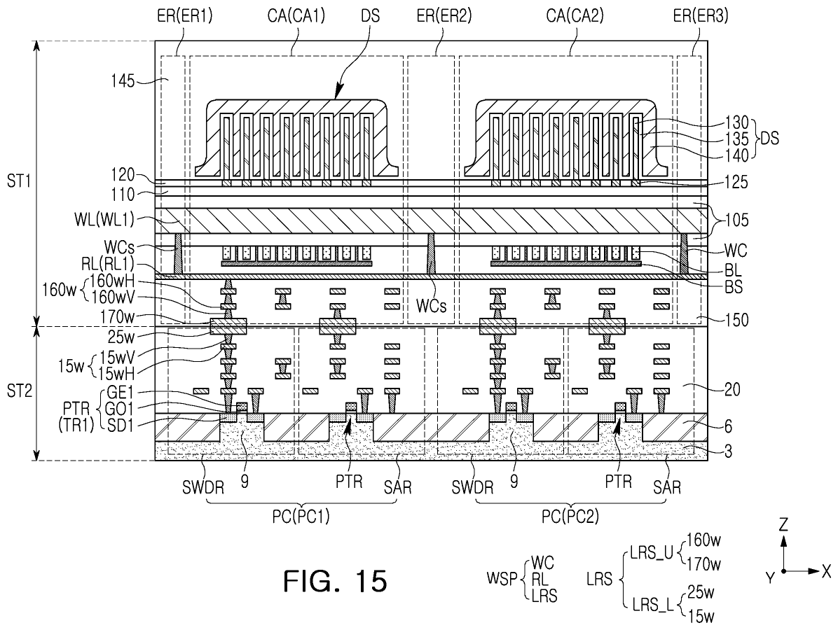

Next, referring to FIGS. 14 and 15, an example of a semiconductor device according to an example embodiment of the present disclosure will be described. FIG. 14 is a conceptual cross-sectional view illustrating a modified example of the routing contacts WC in FIGS. 7A-7D, and FIG. 15 is a cross-sectional view illustrating a modified example of the routing contacts WC in FIG. 9A.

Referring to FIGS. 14 and 15, in each of the connection regions ER, a plurality of the routing contacts WC may be disposed on one word line WL, but the example embodiment is not limited thereto. For example, as in FIGS. 14 and 15, in each of the connection regions ER, the one routing contact WCs may be disposed on one word line WL. Accordingly, the first word line WL1 crossing the first memory block region CA1, the second connection region ER2 and the second memory block region CA2 may be in contact with and connected to one routing contact WCs in the first connection region ER1, may be in contact with and connected to one routing contact WCs in the second connection region ER2, may be in contact with and connected to one routing contact WCs in the third connection region ER3.

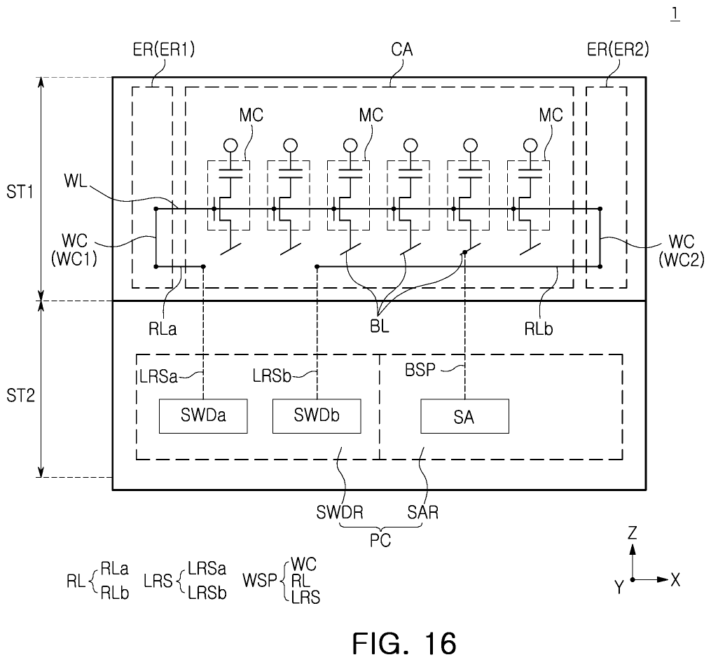

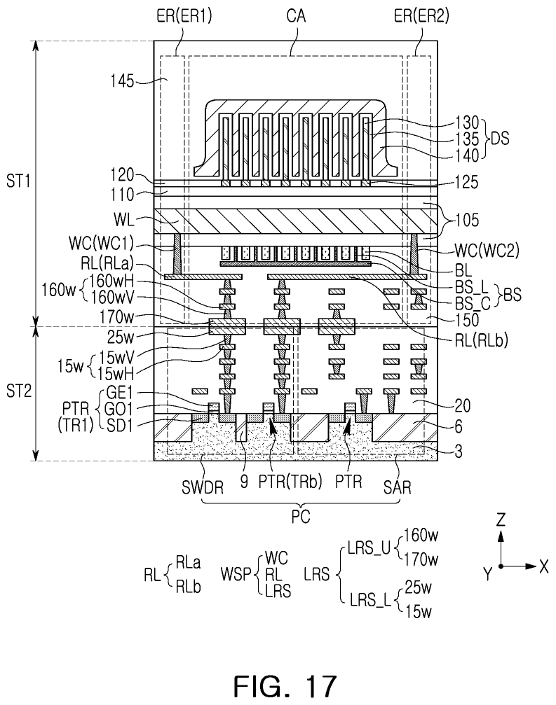

Next, referring to FIGS. 16 and 17, an example of a semiconductor device according to an example embodiment of the present disclosure will be described. FIG. 16 is a conceptual cross-sectional view illustrating a modified example of the sub-word line driver SWD and the word line signal path WSP in FIG. 3, and FIG. 17 is a conceptual cross-sectional view illustrating a modified example of the sub-word line driver SWD and the word line signal path WSP in the cross-sectional structure taken along line I-I′ of FIG. 5A.

Referring to FIGS. 16 and 17, the sub-word line driver (SWD) described in FIG. 3 may be replaced with a plurality of sub-word line drivers SWDa and SWDb electrically connected to one word line WL crossing the memory block region CA in the sub-word line driver region SWDa of the peripheral circuit region PC vertically overlapping (e.g., vertically overlapped by) the one memory block region CA. For example, in order to increase the driving capability of the sub-word line driver, the plurality of sub-word line drivers SWDa and SWDb may be electrically connected to the one word line WL. For example, the plurality of sub-word line drivers SWDa and SWDb may include a first sub-word line driver SWDa and a second sub-word line driver SWDb that are electrically connected to the one word line WL. The first and second sub-word line drivers SWDa and SWDb may be adjacent to each other or may be spaced apart from each other.

Each of the first and second sub-word line drivers SWDa and SWDb may include the transistors PT, NT1 and NT2 as described with respect to FIG. 2B. Accordingly, the peripheral transistors PTR described with respect to FIG. 5A may include a first peripheral transistor TR1 and a second peripheral transistor TRb, which may be one of the transistors PT, NT1 and NT2 of the first sub-word line driver SWD (see FIG. 2B). The first peripheral transistor TR1 and the second peripheral transistor TRb may vertically overlap (e.g., be vertically overlapped by) the memory block region CA. The first peripheral transistor TR1 and the second peripheral transistor TRb may vertically overlap (e.g., be vertically overlapped by) the data storage structure DS.

In a word line signal path WSP electrically connecting the plurality of sub-word line drivers SWDa and SWDb and the one word line WL, the routing interconnection line RL may be divided into a first routing interconnection line RLa connected to the first routing contact WC1 in the first connection region ER1, and a second routing interconnection line RLb connected to the second routing contact WC2 in the second connection region ER2, and the lower routing structure LRS may be divided into a first lower routing structure LRSa electrically connecting the first routing interconnection line RLa and the first sub-word line driver SWDa, and a second lower routing structure LRSb electrically connecting the second routing interconnection line RLb and the second sub-word line driver SWDb. Each of the first and second lower routing structures LRSa and LRSb may include the word line peripheral interconnection structure 15w, the second word line bonding pad 25w, the first word line bonding pad 170w, and the word line lower interconnection structure 160w, as illustrated in FIG. 5A.

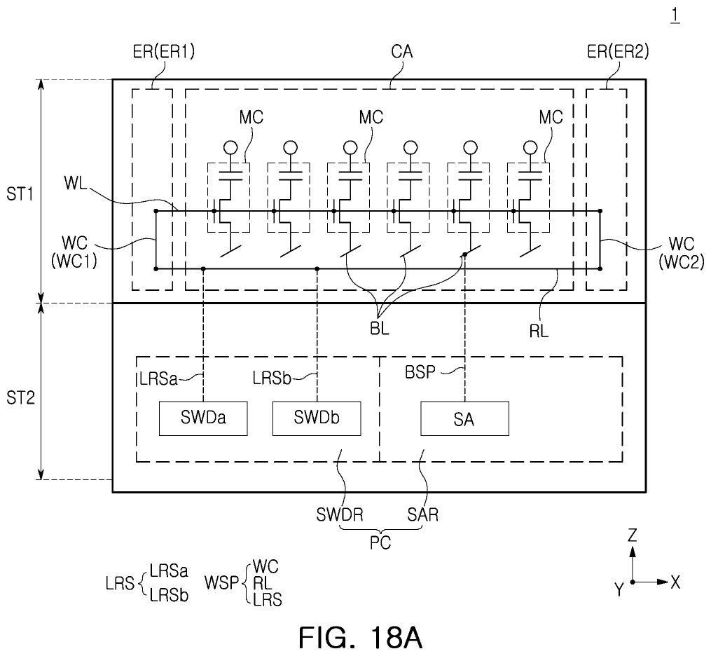

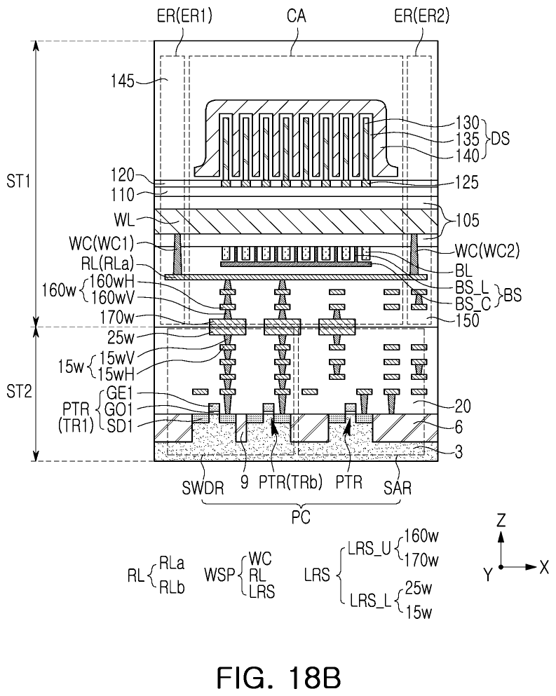

Next, referring to FIGS. 18A and 18B, an example of a semiconductor device according to an example embodiment of the present disclosure will be described. FIG. 18A is a conceptual cross-sectional view illustrating a modified example of the routing interconnection line RL of the word line signal path WSP in FIG. 16, and FIG. 18B is a view illustrating a modified example of the routing interconnection line RL of the word line signal path WSP in FIG. 17.

Referring to FIGS. 18A and 18B, the first routing interconnection line RLa and the second routing interconnection line RLb, which are separated from each other in FIGS. 16 and 17, may be replaced with one routing interconnection line RL. For example, the routing interconnection line RL may continuously extend from a portion in contact with the first routing contact WC1 in the first connection region ER1 to a portion in contact with the second routing contact WC2 in the second connection region ER2. Accordingly, the one routing interconnection line RL may be electrically connected to the first sub-word line driver SWDa through the first lower routing structure LRSa, and may be electrically connected to the second sub-word line driver SWDb through the second lower routing structure LRSb.

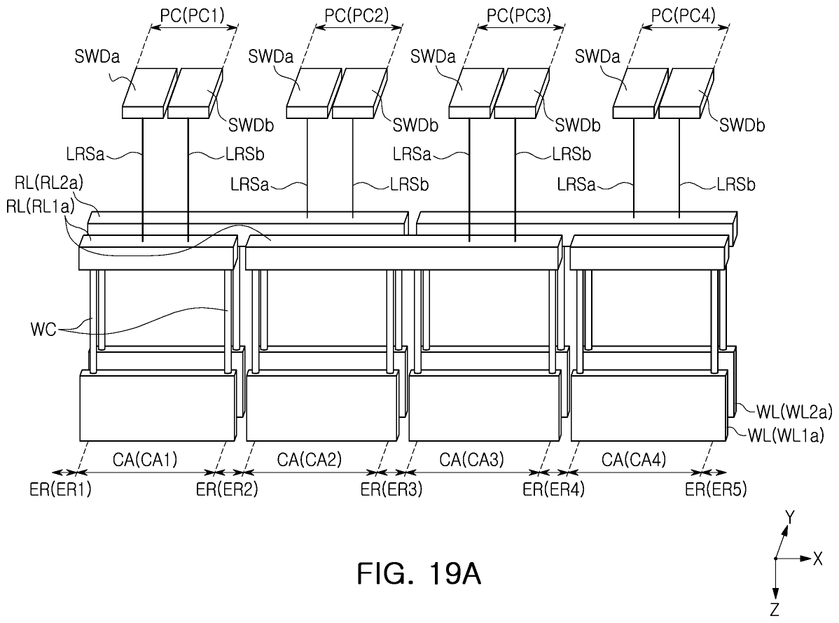

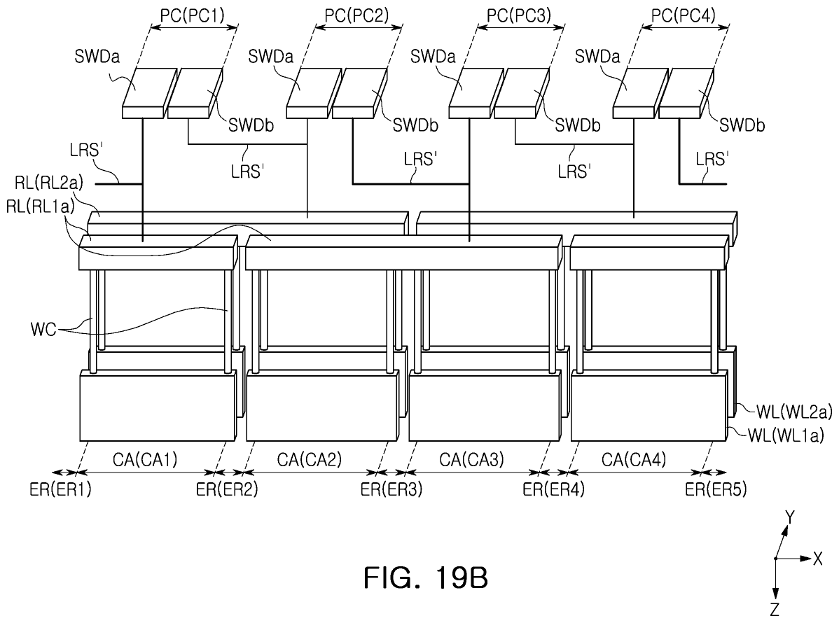

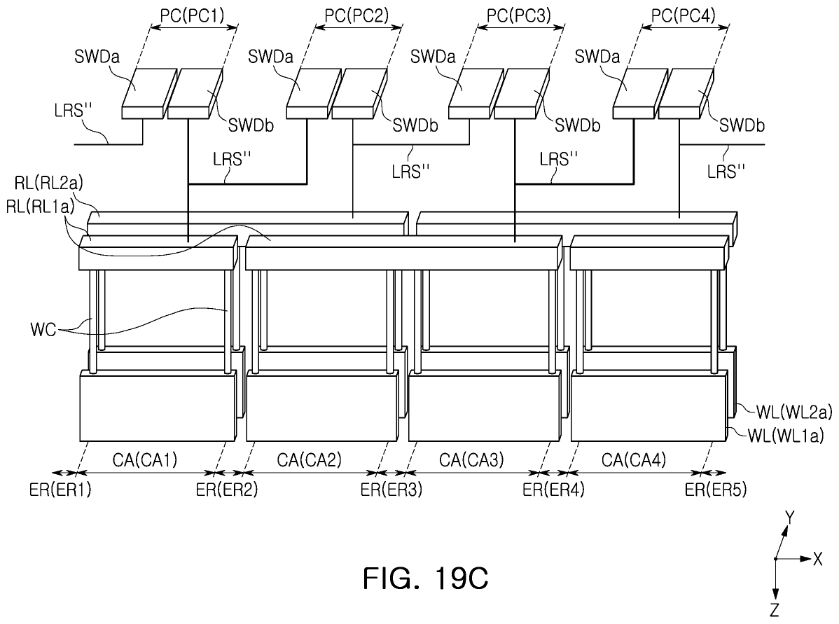

In the example embodiments of FIGS. 16 to 18B described above, one word line WL may be electrically connected to a plurality of sub-word line drivers SWDa and SWDb disposed in the sub-word line driver region SWDR in the peripheral circuit region PC vertically overlapping (e.g., vertically overlapped by) the one memory block region CA. In FIGS. 19A, 19B and 19C, an example in which the memory block regions CA in the example embodiments of FIGS. 16 to 18B are arranged in plural form will be described. FIGS. 19A, 19B and 19C are conceptual perspective views illustrating the first to fourth memory block regions CA1, CA2, CA3 and CA4 and the first to fifth connection regions ER1, ER2, ER3, ER4 and ER5, and first and second word lines WL1a and WL2a, among the first to fourth word lines WL1a, WL2a, WL3a and WL4a, described with respect to FIGS. 12A-12C, and first and second routing interconnection lines RL1a and RL2a, among the first to fourth routing interconnection lines RL1a, RL2a, RL3a, and RL4a described with respect to FIGS. 12A-12C, as well as illustrating an electrical connection relationship between the first and second routing interconnection lines RL1a and RL2a and the sub-word line drivers SWDa and SWDb described with respect to the example embodiments of FIGS. 16 to 18B. Here, the first and second word lines WL1a and WL2a in FIGS. 12A-12C are illustrated and described, but the first and second word lines WL1a and WL2a may be replaced with the first and second word lines WL1 and WL2 as illustrated in FIG. 8 or the first and second word lines WL1b and WL2b as illustrated in FIG. 13.

First, referring to any one embodiment of FIGS. 16 to 18B, and FIGS. 12A-12C and 19A, the peripheral circuit regions PC may include first to fourth peripheral circuit regions PC1, PC2, PC3 and PC4 vertically overlapping (e.g., vertically overlapped by) the first to fourth memory block regions CA1, CA2, CA3 and CA4, respectively. Each of the first to fourth peripheral circuit regions PC1, PC2, PC3 and PC4 may include the first and second routing interconnection lines RLa and RLb described in the example embodiment of FIGS. 16 to 17. Each of the first and second routing interconnection lines RLa and RLb may be electrically connected to corresponding one of the first and second sub-word line drivers SWDa and SWDb. Each of the first to fourth peripheral circuit regions PC1, PC2, PC3 and PC4 may include the first and second sub-word line drivers SWDa and SWDb.

As shown in FIG. 19A, one of the first routing interconnection lines RL1a continuously crossing the second memory block region CA2, the second connection region ER2 and the third memory block region CA3 and extending into the second and fourth connection regions ER2 and ER4 may be electrically connected to the first and second sub-word line drivers SWDa and SWDb that do not vertically overlap (e.g., are not vertically overlapped by) the second memory block region CA2 but vertically overlap (e.g., are vertically overlapped by) the third memory block region CA3. The one first routing interconnection line RL1a may be electrically connected to the first and second sub-word line drivers SWDa and SWDb through the first and second lower routing structures LRSa and LRSb as described above. Accordingly, the first word line WL1a electrically connected to the first routing interconnection line RL1a may be electrically connected to the first and second sub-word line drivers SWDa and SWDb. Accordingly, the first word line WL1a may be electrically connected to the first and second sub-word line drivers SWDa and SWDb through the routing contacts WC, the first routing interconnection line RL1a, and the first and second lower routing structures LRSa and LRSb.

One of the second routing interconnection lines RL2a continuously crossing the first memory block region CA1, the second connection region ER2 and the second memory block region CA2, and extending into the first and third connection regions ER1 and ER3 may be electrically connected to the first and second sub-word line drivers SWDa and SWDb that do not vertically overlap (e.g., are not vertically overlapped by) the first memory block region CA1 but vertically overlap (e.g., are vertically overlapped by) the second memory block region CA2. The one second routing interconnection line RL2a may be electrically connected to the first and second sub-word line drivers SWDa and SWDb through the first and second lower routing structures LRSa and LRSb as described above. Accordingly, the second word line WL2a, which is electrically connected to the second routing interconnection line RL2a, may be electrically connected to the first and second sub-word line drivers SWDa and SWDb. Accordingly, the second word line WL2a may be electrically connected to the first and second sub-word line drivers SWDa and SWDb through the routing contacts WC, the second routing interconnection line RL2a, and the first and second lower routing structures LRSa and LRSb.

Next, referring to FIG. 19B, a modified example of the electrical connection relationship between the word lines WL and the sub-word line drivers SWDa and SWDb described in FIG. 19A will be described.

Referring to FIG. 19B, the first and second lower routing structures LRSa and LRSb (see FIG. 19A) described in FIG. 19A may be replaced with lower routing structures LRS' as illustrated in FIG. 19B.

One of the first routing interconnection lines RL1a continuously crossing the second memory block region CA2, the third connection region ER3 and the third memory block region CA3, and extending into the second and fourth connection regions ER2 and ER4 may be electrically connected to the first sub-word line driver SWDa vertically overlapping (e.g., vertically overlapped by) the third memory block region CA3 and the second sub-word line driver SWDb vertically overlapping (e.g., vertically overlapped by) the second memory block region CA2. The lower routing structure LRS' may electrically connect the first routing interconnection line RL1a and the first sub-word line driver SWDa, and may electrically connect the first routing interconnection line RL1a and the second sub-word line driver SWDb. Accordingly, the first word line WL1a may be electrically connected to the first and second sub-word line drivers SWDa and SWDb through the routing contacts WC, the first routing interconnection line RL1a, and the lower routing structure LRS′.

One of the second routing interconnection lines RL2a continuously crossing the first memory block region CA1, the second connection region ER2 and the second memory block region CA3, and extending into the first and third connection regions ER1 and ER3 may be electrically connected to the first sub-word line driver SWDa vertically overlapping (e.g., vertically overlapped by) the second memory block region CA2 and the second sub-word line driver SWDb vertically overlapping (e.g., vertically overlapped by) the first memory block region CA1. The lower routing structure LRS' may electrically connect the second routing interconnection line RL2a electrically connected to the second word line WL2a to the first sub-word line driver SWDa, and may electrically connect the second routing interconnection line RL2a to the second sub-word line driver SWDb. Accordingly, the second word line WL2a may be electrically connected to the first and second sub-word line drivers SWDa and SWDb through the routing contacts WC, the second routing interconnection line RL2a, and the lower routing structure LRS′.

Next, referring to FIG. 19C, a modified example of the electrical connection relationship between the word lines WL and the sub-word line drivers SWDa and SWDb described with respect to FIG. 19A will be described.

Referring to FIG. 19C, the first and second lower routing structures LRSa and LRSb (see FIG. 19A) described in FIG. 19A may be replaced with lower routing structures LRS″ as illustrated in FIG. 19C.

One of the first routing interconnection lines RL1a continuously crossing the second memory block region CA2, the third connection region ER3 and the third memory block region CA3, and extending into the second and fourth connection regions ER2 and ER4 may be electrically connected to the second sub-word line driver SWDb vertically overlapping (e.g., vertically overlapped by) the third memory block region CA3, and the first sub-word line driver SWDa vertically overlapping (e.g., vertically overlapped by) the fourth memory block region CA4. The lower routing structure LRS″ may electrically connect the first routing interconnection line RL1a and the first sub-word line driver SWDa, and may electrically connect the first routing interconnection line RL1a and the second sub-word line driver SWDb. Accordingly, the first word line WL1a may be electrically connected to the first and second sub-word line drivers SWDa and SWDb through the routing contacts WC, the first routing interconnection line RL1a, and the lower routing structure LRS″.

One of the second routing interconnection lines RL2a continuously crossing the first memory block region CA1, the second connection region ER2 and the second memory block region CA2, and extending into the first and third connection regions ER1 and ER3 may be electrically connected to the first sub-word line driver SWDa vertically overlapping (e.g., vertically overlapped by) the second memory block region CA2 and the second sub-word line driver SWDb vertically overlapping (e.g., vertically overlapped by) the first memory block region CA1. The lower routing structure LRS″ may electrically connect the second routing interconnection line RL2a electrically connected to the second word line WL2a to the first sub-word line driver SWDa, and may electrically connect the second routing interconnection line RL2a and the second sub-word line driver SWDb. Accordingly, the second word line WL2a may be electrically connected to the first and second sub-word line drivers SWDa and SWDb through the routing contacts WC, the second routing interconnection line RL2a, and the lower routing structure LRS″.

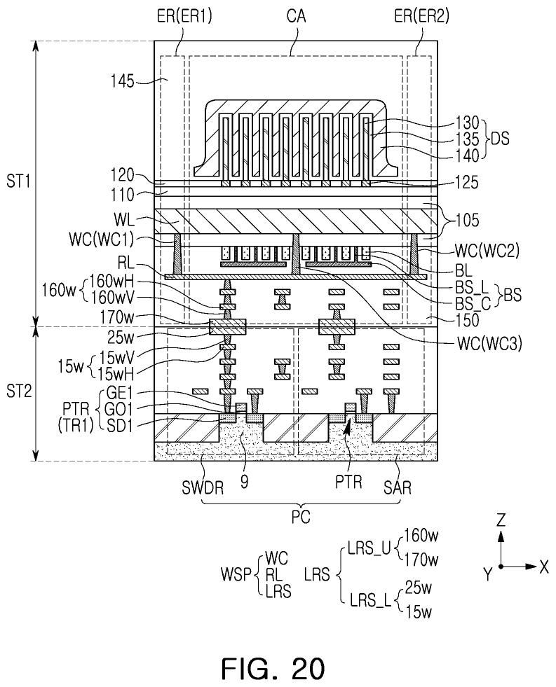

Next, referring to FIG. 20, an example of a semiconductor device according to an example embodiment of the present disclosure will be described. FIG. 20 is a conceptual cross-sectional view illustrating a modified example of the word line signal path WSP in the cross-sectional structure taken along line I-I′ of FIG. 5A.

Referring to FIG. 20, in the word line signal path WSP, the routing contacts WC may further include at least one third routing contact WC3 disposed between the routing interconnection line RL and the word line WL in the memory block region CA, and passing between the bit lines BL. The word line WL crossing the one memory block region CA may be in contact with the first and second routing contacts WC1 and WC2 in the connection regions ER and the third routing contact WC3 in the memory block region CA.

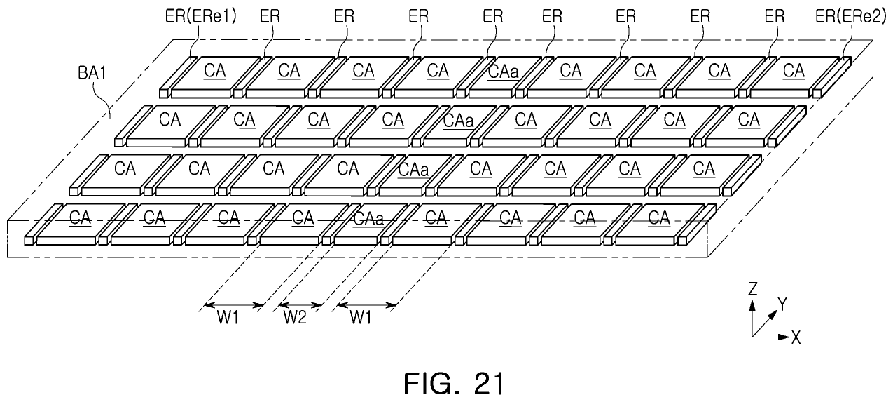

Next, referring to FIG. 21, an example of a semiconductor device according to an example embodiment of the present disclosure will be described. FIG. 21 is a conceptual perspective view illustrating a modified example of the memory block regions CA disposed in the first bank region BA1 of FIG. 1B.

Referring to FIG. 21, at least one intermediate memory block region CAa of the memory block regions CA arranged in the first direction (X-direction) described in FIG. 1B may have a different width than other memory block regions CA. Here, the intermediate memory block region CAa may be defined as a second memory block region CAa, and the remaining memory block regions CA may be defined as the first memory block regions CA. The second memory block region CAa may be disposed between the first memory block regions CA.

A width W2 of the second memory block region CAa in the first direction (2 direction) may be smaller than a width W1 of each of the first memory block regions CA in the first direction (X-direction). The widths of the first and second memory block regions CA and CAa in the second direction (Y-direction) may be the same. Accordingly, ‘m’ number of memory cells MC arranged sequentially in the first direction (X-direction) may be disposed in the second memory block region CAa, and ‘n’ number of memory cells (MC) arranged sequentially in the first direction (X-direction) may be arranged in one first memory block region CA among the first memory block regions CA. The ‘n’ and ‘m’ are natural numbers, and the ‘n’ may be a natural number larger than the ‘m.’

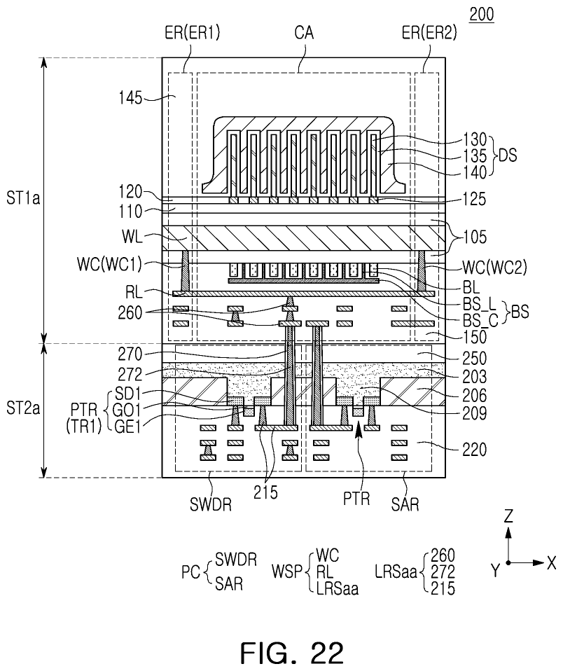

Next, examples of semiconductor devices according to an example embodiment of the present disclosure will be described with reference to FIGS. 22, 23 and 24, respectively. FIGS. 22, 23 and 24 are cross-sectional views illustrating modified examples of the first structure ST1 and the second structure ST2 in the cross-sectional structure taken along line I-I′ of FIG. 5A.

First, referring to FIG. 22, the first structure ST1 according to the embodiments of FIGS. 1A to 21 may be replaced with the first structure STla as illustrated in FIG. 22. For example, the first structure STla may be formed by omitting the first bonding pads 170w from the first structure ST1 according to the example embodiments of FIGS. 1A to 21, and replacing the word line lower interconnection structure 160w with the word line lower interconnection structure 260 as illustrated in FIG. 22. The word line lower interconnection structure 260 may include at least one horizontal portion and at least one vertical portion. The word line lower interconnection structure 260 may be connected to the routing interconnection line RL.

The second structure ST2 according to the example embodiments of FIGS. 1A to 21 may be replaced with the second structure ST2a as illustrated in FIG. 22. The second structure ST2a may include a substrate 203 and a device isolation region 206 defining active regions 209 below the substrate 203. The substrate 203 may be a semiconductor substrate.

The second structure ST2a may include peripheral circuit transistors PTR disposed below the substrate 203, a peripheral interconnection structure 215 electrically connected to the peripheral circuit transistors PTR below the peripheral circuit transistors PTR, a lower insulating structure 220 covering the peripheral transistors PTR and the substrate 203 below (e.g., on a bottom surface of) the substrate 203, and a bonding insulating layer 250 disposed on the substrate 203 and in contact with and bonded to the first insulating structure 150 of the first structure STla.

Each of the peripheral circuit transistors PTR may include peripheral gate structures GE1 and GO1 disposed below the active region 209, and peripheral source/drain regions SD1 disposed in the active region 209 disposed on opposite (e.g., both) sides of the peripheral gate structures GE1 and GO1. The peripheral gate structures GE1 and GO1 may include a peripheral gate dielectric layer GO1 and a peripheral gate electrode GE1 below the peripheral gate dielectric layer GO1.

The second structure ST2a may include the same peripheral circuit region PC as described above. Among the peripheral circuit transistors PTR, a first peripheral transistor TR1 disposed in the sub-word line driver region SWDR may be transistors PT, NT1 and NT2 of the sub-word line driver SWD (see FIG. 2B).

The first and second structures STla and ST2a may further include through-electrode structures 270 and 272. For example, any one of the through-electrode structures 270 and 272 may include a through-electrode 272 extending downwardly by penetrating through the substrate 203 and connected to the peripheral interconnection structure 215, and extending upwardly by penetrating through the substrate 203 and connected to the word line lower interconnection structure 260, and an insulating spacer 270 surrounding a side surface of the through-electrode 272.

The lower routing structure LRS in the example embodiments of FIGS. 1A to 21 described above may be replaced with a lower routing structure LRSaa including the peripheral interconnection structure 215, the through-electrode 272, and the word line lower interconnection structure 260.

The word line signal path WSP in the example embodiments of FIGS. 1A to 21 described above may be replaced by a word line signal path WSP including the lower routing structure LRSaa, the routing interconnection line RL, and the routing contacts WC. Accordingly, the first peripheral transistor TR1, which may be the sub-word line driver (SWD in FIG. 2B), may be electrically connected to the word line WL through the lower routing structure LRSaa, the routing interconnection line RL, and the routing contacts WC.

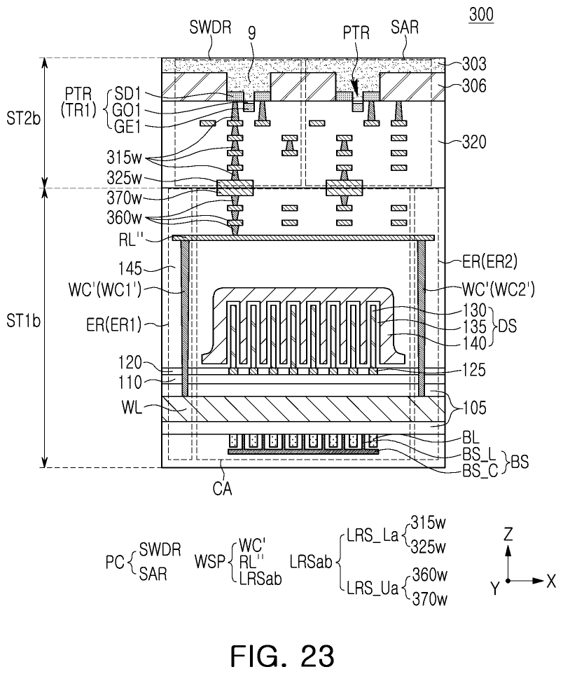

Next, referring to FIG. 23, the first structure ST1 according to the example embodiments of FIGS. 1A to 21 may be replaced with the first structure ST1b as illustrated in FIG. 23. For example, the first structure ST1b may replace the first structure ST1 according to the example embodiments of FIGS. 1A to 21, the routing contacts WC may be replaced with routing contacts WC′ disposed on the word line WL in the connection regions ER, the routing interconnection line RL may be replaced with routing interconnection line RL″ connected to upper surfaces of the routing contacts WC′ and crossing the memory block region CA at a level higher than the data storage structure DS, the word line lower routing structure 160w may be replaced with a word line upper routing structure 360w disposed on the routing interconnection line RL″, and the first bonding pad 170w may be replaced with a first bonding pad 370w connected to the word line upper routing structure 360w and having an upper surface coplanar with an upper surface of the upper insulating structure 145. The routing contacts WC′ may include a first routing contact WC1′ in contact with and connected to an upper surface of the word line WL in the first connection region ER1, and a second routing contact WC2′ connected to and in contact with the upper surface of the word line WL a second connection region ER2. Accordingly, the upper structure LRS_U in the embodiments of FIGS. 1A to 21 may be replaced with an upper structure LRS_Ua including the word line upper routing structure 360w and the first bonding pad 370w.

The second structure ST2 according to the example embodiments of FIGS. 1A to 21 may be replaced with the second structure ST2b as illustrated in FIG. 23. The second structure ST2b may be disposed on the first structure ST1b.

The second structure ST2b may further include a substrate 303 and a device isolation region 306 defining active regions 309 below the substrate 303. The substrate 303 may be a semiconductor substrate. The second structure ST2b may include peripheral circuit transistors PTR disposed below the substrate 303, a peripheral interconnection structure 315w electrically connected to the peripheral circuit transistors PTR below the peripheral circuit transistors PTR, a lower insulating structure 320 covering the peripheral transistors PTR and the substrate 303 below the substrate 303 (e.g., on a bottom surface thereof), and a second bonding pad 325w connected to the peripheral interconnection structure 315w and having a lower surface coplanar with a lower surface of the lower insulating structure 320. The peripheral transistors PTR may be the same as the peripheral transistors PTR described in FIG. 22. The lower structure LRS_L in the example embodiments of FIGS. 1A to 21 may be replaced with a lower structure LRS_La including the peripheral interconnection structure 315w and the second bonding pad 325w.

The lower routing structure LRS in the example embodiments of FIGS. 1A to 21 described above may be replaced with a lower routing structure LRSab including the lower structure LRS_La and the upper structure LRS_Ua.

The word line signal path WSP in the example embodiments of FIGS. 1A to 21 described above may be replaced with a word line signal path WSP including the lower routing structure LRSab, the routing interconnection line RL″ and the routing contacts WC′. Accordingly, the first peripheral transistor TR1, which may be the sub-word line driver SWD (see FIG. 2B) may be electrically connected to the word line WL through the lower routing structure LRSab, the routing interconnection line RL″, and the routing contacts WC′.

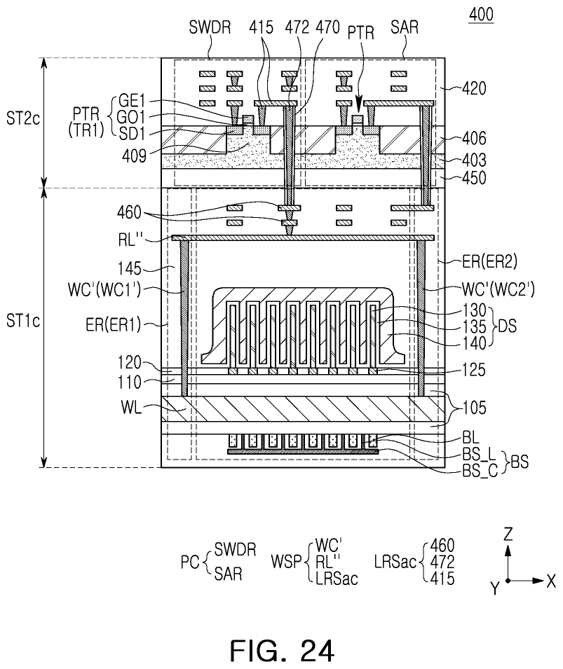

Next, referring to FIG. 24, the first structure ST1b in FIG. 23 may be replaced with a first structure ST1c as illustrated in FIG. 24. For example, the first structure ST1c may formed by omitting the first bonding pad 370w from the first structure ST1b in FIG. 23, and replacing the word line upper interconnection structure 360w with a word line upper interconnection structure 460 as shown in FIG. 24. The word line upper interconnection structure 460 may include at least one horizontal portion and at least one vertical portion. The word line upper interconnection structure 360 may be connected to the routing interconnection line RL″.

The second structure ST2b in FIG. 23 may be replaced with a second structure ST2c as illustrated in FIG. 24. The second structure ST2c may include a substrate 403 and a device isolation region 406 defining active regions 409 on the substrate 403. The substrate 403 may be a semiconductor substrate. The second structure ST2c may include peripheral transistors PTR disposed on the substrate 403, a peripheral interconnection structure 415 electrically connected to peripheral circuit transistors PTR on the peripheral transistors PTR, a lower insulating structure 420 covering the peripheral transistors PTR and the substrate 403 on the substrate 403, and a bonding insulating layer 450 disposed below the substrate 403 and in contact with and bonded to the upper insulating structure 145 of the first structure ST1c. Each of the peripheral circuit transistors PTR may include peripheral gate structures GE1 and GO1 disposed on the active region 409, and peripheral source/drain regions SD1 disposed in the active region 409 disposed on opposite (e.g., both) sides of the peripheral gate structures GE1 and GO1.

The second structure ST2c may include the same peripheral circuit region PC as described above. A first peripheral transistor TR1 disposed in the sub-word line driver region SWDR, among the peripheral circuit transistors PTR may be the transistors PT, NT1 and NT2 of the sub-word line driver SWD (see FIG. 2B).

The first and second structures ST1c and ST2c may further include through-electrode structures 470 and 472. For example, any one of the through-electrode structures 470 and 472 may include a through-electrode 472 extending upwardly by penetrating through the substrate 403 and connected to the peripheral interconnection structure 415, and extending downwardly through the substrate 403 and connected to the word line upper interconnection structure 460, and an insulating spacer 470 surrounding a side surface of the through-electrode 472.

The lower routing structure LRS in the example embodiments of FIGS. 1A to 21 described above may be replaced with a lower routing structure LRSac including the peripheral interconnection structure 415, the through-electrode 472, and the word line upper interconnection structure 460.

The word line signal path WSP in the example embodiments of FIGS. 1A to 21 described above may be replaced with a word line signal path WSP including the lower routing structure LRSac, the routing interconnection line RL″ and the routing contacts WC′. Accordingly, the first peripheral transistor TR1, which may be the sub-word line driver SWD (see FIG. 2B) may be electrically connected to the word line WL through the lower routing structure LRSac, the routing interconnection line RL″, and the routing contacts WC′.

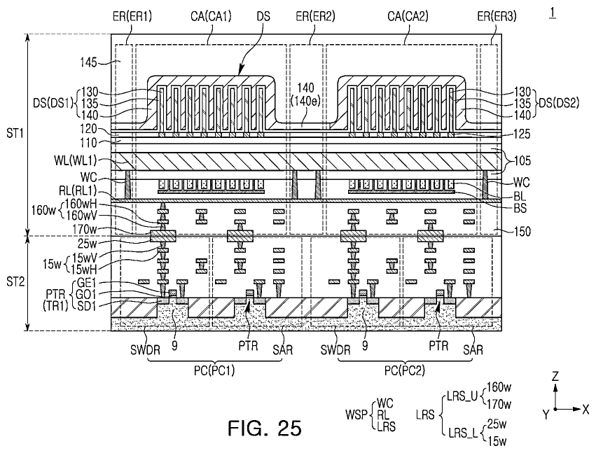

Next, referring to FIG. 25, examples of a semiconductor device according to an example embodiment of the present disclosure will be described. FIG. 25 is a cross-sectional view illustrating a modified example of the data storage structures DS in the cross-sectional structure of FIG. 9A.

Referring to FIG. 25, the data storage structures DS may include a first data storage structure DS1 disposed in the first memory block region CA1, and a second data storage structure DS2 disposed in the second memory block region CA2. In the example of FIG. 25, the second electrode 140 of the first data storage structure DS1 and the second electrode 140 of the second data storage structure DS2 may extend into the connecting regions ER and may be connected to (e.g., in contact with) each other. For example, the second electrodes 140 of the data storage structures DS disposed in the first bank region BA1 as illustrated in FIG. 1B may have extension portions 140e extending into the connection regions ER, and the second electrodes 140 of the data storage structures DS disposed in the first bank region BA1 may be one second electrode 140 continuously connected to each other. Since the second electrodes 140 of the data storage structures DS are connected to each other, the same voltage Vp may be applied to the second electrodes 140 more effectively. Accordingly, the data storage structures DS may store information more stably and reliably. The routing contacts WC may overlap (e.g., be overlapped by) the second electrode 140 of the data storage structures DS in the vertical direction (Z-direction).

According to example embodiments, the performance of the semiconductor device may be improved because a voltage may be applied to a word line WL in a memory block region, through first and second connection regions disposed on opposite (e.g., both) sides of the memory block region.

Advantages and effects of the present application are not limited to the foregoing content and may be more easily understood in the process of describing a specific example embodiment of the present disclosure.

Although example embodiments of the present disclosure have been described with reference to the accompanying drawings, it will be understood by those skilled in the art that the present disclosure may be implemented in other specific forms without changing its scope. Therefore, it should be understood that the example embodiments described above are merely examples and not intended to be limiting.

What is claimed is:

1. A semiconductor device comprising:
a first structure having a first connection region, a second connection region, and a first memory block region that is between, in a first direction, the first connection region and the second connection region; and
a second structure vertically overlapping with the first structure, wherein the first structure includes:
first memory cells in the first memory block region; and
a first word line crossing the first memory block region and extending into the first and second connection regions, and electrically connected to the first memory cells,
wherein the second structure has a first peripheral circuit region, at least a portion of which is vertically overlapping with the first memory block region,
wherein the second structure includes a first sub-word line driver in the first peripheral circuit region,
wherein the first and second structures further include a first word line signal path electrically connecting the first word line and the first sub-word line driver, and
wherein the first word line signal path includes at least one first routing contact coupled to the first word line in the first connection region, and at least one second routing contact coupled to the first word line in the second connection region.

2. The semiconductor device of claim 1,
wherein the first word line signal path further includes a first routing interconnection line electrically connected to the at least one first routing contact and the at least one second routing contact,
wherein the first routing interconnection line comprises a first portion adjacent the at least one first routing contact and a second portion adjacent the at least one second routing contact, and
wherein the first routing interconnection line extends continuously from the first portion to the second portion, and crosses the first memory block region.

3. The semiconductor device of claim 2,
wherein the first word line signal path further includes a first lower routing structure electrically connecting the first routing interconnection line and the first sub-word line driver, and
wherein the first lower routing structure and the first routing interconnection line are coupled to each other below the first memory cells.

4. The semiconductor device of claim 1, wherein each of the first memory cells includes a cell transistor and a data storage structure electrically connected to the cell transistor,
wherein the cell transistor includes:
a first source/drain region and a second source/drain region at a higher level than the first source/drain region;
a channel region between the first and second source/drain regions;
a gate dielectric layer in contact with a side surface of the channel region; and
the first word line in contact with the gate dielectric layer, and wherein the data storage structure includes:
a first electrode electrically connected to the second source/drain region;
a second electrode on an upper surface and a side surface of the first electrode; and
a dielectric layer between the first electrode and the second electrode.

5. The semiconductor device of claim 1, further comprising:
a first bit line crossing the first memory block region in a second direction, intersecting the first word line, and electrically connected to at least one of the first memory cells;
a first sense amplifier in the first peripheral circuit region; and
a first bit line signal path electrically connecting the first bit line and the first sense amplifier.

6. The semiconductor device of claim 1, further comprising:
a second memory block region and a third connection region, wherein the second memory block region is between, in the first direction, the second connection region and the third connection region;
a second peripheral circuit region vertically overlapping with the second memory block region;
second memory cells in the first memory block region;
third memory cells and fourth memory cells in the second memory block region;
a second word line crossing the first memory block region, the second connection region, and the second memory block region, extending into the first and third connection regions, and electrically connected to the second and fourth memory cells;
a second sub-word line driver in the second peripheral circuit region; and
a second word line signal path electrically connecting the second word line and the second sub-word line driver.

7. The semiconductor device of claim 6, wherein the first word line extends in the first direction, extends into the third connection region by crossing the second memory block region, and is electrically connected to the third memory cells.

8. The semiconductor device of claim 7, wherein the first word line signal path further includes at least one third routing contact coupled to the first word line in the third connection region.

9. The semiconductor device of claim 6, wherein the second word line signal path includes:
at least one fourth routing contact coupled to the second word line in the first connection region;
at least one fifth routing contact coupled to the second word line in the second connection region; and
at least one sixth routing contact coupled to the second word line in the third connection region.

10. A semiconductor device comprising:
a first connection region, a second connection region, and a first memory block region that is between, in a first direction, the first connection region and the second connection region;
a first peripheral circuit region vertically overlapping with the first memory block region;
first memory cells in the first memory block region;
a first word line extending into the first and second connection regions by crossing the first memory block region, and electrically connected to the first memory cells;
a sub-word line driver in the first peripheral circuit region; and
a first word line signal path electrically connecting the first word line and the sub-word line driver,
wherein the first word line signal path includes at least one first routing contact coupled to the first word line in the first connection region, and at least one second routing contact coupled to the first word line in the second connection region.

11. The semiconductor device of claim 10,
wherein the first word line signal path further includes a first routing interconnection line electrically connected to the at least one first routing contact and the at least one second routing contact,
wherein the first routing interconnection line comprises a first portion adjacent the at least one first routing contact and a second portion adjacent the at least one second routing contact, and
wherein the first routing interconnection line extends continuously from the first portion to the second portion, and crosses the first memory block region.

12. The semiconductor device of claim 10,
wherein the at least one first routing contact is two or more first routing contacts spaced apart from each other, and
wherein the at least one second routing contact is two or more second routing contacts spaced apart from each other.

13. The semiconductor device of claim 10, further comprising:
a first bit line crossing the first memory block region in a second direction, intersecting the first word line, and electrically connected to one first memory cell of the first memory cells;
a first sense amplifier in the first peripheral circuit region; and
a first bit line signal path electrically connecting the first bit line and the first sense amplifier.

14. A semiconductor device comprising:
a first structure including connection regions and memory block regions alternately and repeatedly arranged in a first direction; and
a second structure arranged in the first direction, including peripheral circuit regions, and vertically overlapping with the first structure,
wherein the connection regions include a first edge connection region, a second edge connection region, and intermediate connection regions between the first edge connection region and the second edge connection region,
wherein each of the memory block regions is between a pair of adjacent connection regions among the connection regions,
wherein the first structure includes:
memory cells in each of the memory block regions; and
word lines electrically connected to the memory cells by crossing the memory block regions and extending into the connection regions,
wherein the second structure includes sub-word line drivers in each of the peripheral circuit regions,
wherein the first and second structures further include word line signal paths electrically connecting the word lines and the sub-word line drivers, and
wherein the word line signal paths include:
routing interconnection lines crossing the memory block regions and extending into the connection regions;
routing contacts in each of the connection regions and electrically connecting the word lines and the routing interconnection lines; and
routing structures electrically connecting the routing interconnection lines and the sub-word line drivers.

15. The semiconductor device of claim 14,
wherein the memory block regions include first memory block regions and a second memory block region between the first memory block regions,
wherein each of the first memory block regions includes ‘n’ number of memory cells,
wherein the second memory block region includes ‘m’ number of memory cells,
wherein the ‘n’ and ‘m’ are natural numbers, and
wherein the ‘n’ is a natural number greater than the ‘m.’

16. The semiconductor device of claim 14,
wherein the first structure further includes bit lines electrically connected to the memory cells,
wherein the second structure further includes sense amplifiers respectively in the peripheral circuit regions, and
wherein the first and second structures further include bit line signal paths electrically connecting the bit lines and the sub-word line drivers.

17. The semiconductor device of claim 14, wherein each of the memory cells includes a cell transistor and a data storage structure electrically connected to the cell transistor, and
wherein the cell transistor includes:
a vertical active pattern including a first source/drain region, a second source/drain region at a higher level than the first source/drain region, and a channel region between the first and second source/drain regions;
a gate dielectric layer in contact with the channel region of the vertical active pattern; and
a word line, among the word lines, in contact with the gate dielectric layer, wherein the word line comprises a gate electrode, and
wherein the data storage structure includes:
a first electrode electrically connected to the second source/drain region;
a second electrode on an upper surface and a side surface of the first electrode; and
a dielectric layer between the first electrode and the second electrode.

18. The semiconductor device of claim 17, wherein the second electrodes of the data storage structures of the memory block regions extend into the intermediate connection regions and are in contact with each other.

19. The semiconductor device of claim 17, further comprising:
back gate lines between the word lines,
wherein each of the back gate lines is between a pair of word lines adjacent to each other, among the word lines, and passes between a pair of vertical active patterns adjacent to each other, among the vertical active patterns.

20. The semiconductor device of claim 14, wherein the word lines cross the memory block regions and the intermediate connection regions and extend into the first and second edge connection regions.
